(19) United States
(12) Patent Application Publication
(10) Pub. No.: US 2022/0371121 A1
(43) Pub. Date: Nov. 24, 2022

(54) EXPOSURE SYSTEM, LASER CONTROL PARAMETER PRODUCTION METHOD, AND ELECTRONIC DEVICE MANUFACTURING METHOD

(71) Applicant: Gigaphoton Inc., Tochigi (JP)

(72) Inventors: Koichi FUJII, Oyama-shi (JP); Osamu WAKABAYASHI, Oyama-shi (JP)

(73) Assignee: Gigaphoton Inc., Tochigi (JP)

(21) Appl. No.: 17/817,197

(22) Filed: Aug. 3, 2022

Related U.S. Application Data
(63) Continuation of application No. PCT/JP2020/012415, filed on Mar. 19, 2020.

(51) Int. Cl. B23K 26/046; B23K 26/082; B23K 26/0622; B23K 26/03; B23K 26/359

(52) U.S. Cl. CPC B23K 26/046; B23K 26/082; B23K 26/0622; B23K 26/03; B23K 26/359; B23K 26/0732

(57) ABSTRACT

An exposure system that performs scanning exposure of a semiconductor substrate by irradiating a reticle with a pulse laser beam includes a laser apparatus configured to emit a pulse laser beam, an illumination optical system through which the pulse laser beam is guided to the reticle, a reticle stage, and a processor configured to control emission of the pulse laser beam from the laser apparatus and movement of the reticle by the reticle stage. The reticle includes a region in which multiple kinds of patterns are arranged in a mixed manner in a scanning width direction orthogonal to a scanning direction of the scanning exposure. The processor instructs the laser apparatus about a target wavelength such that the laser apparatus emits the pulse laser beam of a wavelength with which dispersion of best focus positions corresponding to respective patterns of the multiple kinds of patterns is minimum.

### CROSS-REFERENCE TO RELATED APPLICATIONS

The present application is a continuation application of International Application No. PCT/JP2020/012415, filed on Mar. 19, 2020, the entire contents of which are hereby incorporated by reference.

### BACKGROUND

### 1. Technical Field

The present disclosure relates to an exposure system, a laser control parameter production method, and an electronic device manufacturing method.

### 2. Related Art

Recently, in a semiconductor exposure apparatus, resolving power improvement has been requested along with miniaturization and high integration of a semiconductor integrated circuit. Thus, the wavelength of light discharged from an exposure light source has been shortened. Examples of a gas laser apparatus for exposure include a KrF excimer laser apparatus configured to emit a laser beam having a wavelength of 248 nm approximately and an ArF excimer laser apparatus configured to emit a laser beam having a wavelength of 193 nm approximately.

The KrF excimer laser apparatus and the ArF excimer laser apparatus have a wide spectrum line width of 350 to 400 pm for spontaneous oscillation light. Thus, chromatic aberration occurs in some cases when a projection lens is made of a material that transmits ultraviolet light such as a KrF or ArF laser beam. As a result, resolving power potentially decreases. Thus, the spectrum line width of a laser beam emitted from such a gas laser apparatus needs to be narrowed until chromatic aberration becomes negligible. To narrow the spectrum line width, a line narrowing module (LNM) including a line narrowing element (for example, etalon or grating) is provided in a laser resonator of the gas laser apparatus in some cases. In the following description, a gas laser apparatus that achieves narrowing of the spectrum line width is referred to as a line narrowed gas laser apparatus.

### LIST OF DOCUMENTS

### Patent Documents

Patent Document 1: US Patent Application Publication No. 2015/0070673
Patent Document 2: US Patent Application Publication No. 2011/0205512
Patent Document 3: US Patent Application Publication No. 2006/0035160
Patent Document 4: US Patent Application Publication No. 2003/0227607
Patent Document 5: US Patent Application Publication No. 2018/0196347
Patent Document 6: US Patent Application Publication No. 2019/0245321
Patent Document 7: US Patent Application Publication No. 2004/0012844

### SUMMARY

An exposure system according to an aspect of the present disclosure is an exposure system that performs scanning exposure of a semiconductor substrate by irradiating a reticle with a pulse laser beam. The exposure system includes a laser apparatus configured to emit a pulse laser beam, an illumination optical system through which the pulse laser beam is guided to the reticle, a reticle stage configured to move the reticle, and a processor configured to control emission of the pulse laser beam from the laser apparatus and movement of the reticle by the reticle stage. The reticle includes a region in which multiple kinds of patterns are arranged in a mixed manner in a scanning width direction orthogonal to a scanning direction of the scanning exposure. The processor instructs the laser apparatus about a target wavelength of the pulse laser beam such that the laser apparatus emits the pulse laser beam of a wavelength with which dispersion of best focus positions corresponding to the respective patterns of the multiple kinds of patterns is minimum.

A laser control parameter production method according to another aspect of the present disclosure is a method of producing a laser control parameter, the method being executed by a processor. The laser control parameter includes a wavelength of a pulse laser beam with which a reticle is irradiated. The method includes calculating, by the processor, best focus positions corresponding to respective patterns of multiple kinds of patterns included in the reticle; calculating, by the processor, for each combination of the multiple kinds of patterns, a wavelength of the pulse laser beam with which dispersion of the best focus positions corresponding to the respective patterns of the multiple kinds of patterns included in the combination is minimum; associating and storing, by the processor, the combination of the multiple kinds of patterns and the wavelength of the pulse laser beam with which the dispersion is minimum in a file.

An electronic device manufacturing method according to another aspect of the present disclosure is an electronic device manufacturing method including performing scanning exposure of a photosensitive substrate by irradiating a reticle with a pulse laser beam by using an exposure system to manufacture an electronic device. The exposure system includes a laser apparatus configured to emit the pulse laser beam, the reticle, an illumination optical system through which the pulse laser beam is guided to the reticle, a reticle stage configured to move the reticle, and a processor configured to control emission of the pulse laser beam from the laser apparatus and movement of the reticle by the reticle stage. The reticle includes a region in which multiple kinds of patterns are arranged in a mixed manner in a scanning width direction orthogonal to a scanning direction of the scanning exposure. The processor instructs the laser apparatus about a target wavelength of the pulse laser beam such that the laser apparatus emits the pulse laser beam of a wavelength with which dispersion of best focus positions corresponding to the respective patterns of the multiple kinds of patterns is minimum.

### BRIEF DESCRIPTION OF THE DRAWINGS

Embodiments of the present disclosure will be described below merely as examples with reference to the accompanying drawings.

FIG. 1 is a graph illustrating an exemplary inter-pattern best focus difference.

FIG. 2 schematically illustrates the configuration of an exposure system according to a comparative example.

FIG. 3 illustrates an exemplary output pattern of a light emission trigger signal transmitted from an exposure control unit to a laser control unit.

FIG. 4 illustrates an exemplary exposure pattern of step-and-scan exposure on a wafer.

FIG. 5 illustrates the relation between one scanning field and a static exposure area on a wafer.

FIG. 6 is an explanatory diagram of the static exposure area.

FIG. 7 illustrates an exemplary configuration of a lithography system according to Embodiment 1.

FIG. 8 illustrates an exemplary configuration of a laser apparatus.

FIG. 9 is a plan view schematically illustrating an exemplary reticle pattern.

FIG. 10 exemplarily illustrates focus curves of patterns (1) to (3) in case 1 illustrated in the upper part of FIG. 9.

FIG. 11 exemplarily illustrates focus curves of the patterns (1) and (2) in case 2 illustrated in the lower part of FIG. 9.

FIG. 12 illustrates an exemplary relation among a reticle pattern, an optimum wavelength, and a target wavelength.

FIG. 13 is a flowchart illustrating exemplary processing performed by a lithography control unit of Embodiment 1.

FIG. 14 is a flowchart illustrating exemplary processing performed by the lithography control unit of Embodiment 1.

FIG. 15 is a flowchart illustrating exemplary processing contents applied to step S13 in FIG. 13.

FIG. 16 is a plan view schematically illustrating part of the reticle pattern.

FIG. 17 is a cross-sectional view taken along line 17-17 in FIG. 16.

FIG. 18 is a table listing exemplary data stored in a file A.

FIG. 19 is a table listing exemplary data stored in a file B.

FIG. 20 is a flowchart illustrating exemplary processing performed by an exposure control unit of Embodiment 1.

FIG. 21 is a flowchart illustrating exemplary processing performed by a laser control unit of Embodiment 1.

FIG. 22 illustrates an exemplary relation among the reticle pattern, the optimum wavelength, the target wavelength, and an integration spectrum wavelength in a lithography system according to Embodiment 2.

FIG. 23 is a flowchart illustrating exemplary processing performed by an exposure control unit of Embodiment 2.

FIG. 24 illustrates an exemplary configuration of a lithography system according to Embodiment 3.

FIG. 25 is a flowchart illustrating exemplary processing at a lithography control unit of Embodiment 3.

FIG. 26 illustrates another exemplary configuration of a laser apparatus.

FIG. 27 illustrates an exemplary configuration of a semiconductor laser system.

FIG. 28 is a conceptual diagram of a spectrum line width achieved by chirping.

FIG. 29 is a schematic diagram illustrating the relation among current flowing through a semiconductor laser, wavelength change by chirping, a spectrum waveform, and light intensity.

FIG. 30 is a graph for description of a rising time of a semiconductor optical amplifier.

FIG. 31 schematically illustrates an exemplary configuration of an exposure apparatus.

### DESCRIPTION OF EMBODIMENTS

### <Contents>

### 1. Terms

2. Overview of exposure system according to comparative example

2.1 Configuration

2.2 Operation

2.3 Exemplary exposure operation on wafer

2.4 Relation between scanning field and static exposure area

2.5 Problem

### 3. Embodiment 1

3.1 Overview of lithography system
3.1.1 Configuration
3.1.2 Operation

3.2 Exemplary laser apparatus
3.2.1 Configuration
3.2.2 Operation
3.2.3 Other

3.3 Exemplary focus curve of reticle pattern

3.4 Exemplary contents of processing by lithography control unit

3.5 Exemplary contents of processing by exposure control unit

3.6 Exemplary contents of processing by laser control unit

3.7 Effect

3.8 Other

### 4. Embodiment 2

4.1 Configuration

4.2 Operation

4.3 Effect

### 5. Embodiment 3

5.1 Configuration

5.2 Operation

5.3 Effect

5.4 Other

6. Dispersion of best focus positions of patterns
7. Exemplary excimer laser apparatus that uses solid-state laser device as oscillator

7.1 Configuration

7.2 Operation

7.3 Description of semiconductor laser system
7.3.1 Configuration
7.3.2 Operation
7.3.3 Other

7.4 Effect

7.5 Other

8. Hardware configurations of various control units
9. Electronic device manufacturing method

### 10. Other

Embodiments of the present disclosure will be described below in detail with reference to the accompanying drawings. The embodiments described below are examples of the present disclosure, and do not limit the contents of the present disclosure. Not all configurations and operations described in each embodiment are necessarily essential as configurations and operations of the present disclosure. Components identical to each other are denoted by an identical reference sign, and duplicate description thereof will be omitted.

### 1. Terms

Terms used in the present disclosure are defined as described below.

A critical dimension (CD) is the dimension of a minute pattern formed on a wafer such as a semiconductor.

Overlay is overlay of a minute pattern formed on a wafer such as a semiconductor.

A spectrum line width Δλ is an index value of a spectrum line width that affects exposure performance. The spectrum line width Δλ may be, for example, a bandwidth with which the integral energy of a laser spectrum is 95%.

CD uniformity (CDU; critical dimension uniformity) is uniformity of the line width CD of a pattern formed on a wafer. The CDU is evaluated by various methods and statistically evaluated by using, for example, a standard deviation (σ) within a lot, within a wafer, or within a scanning field. Variance occurs to device operation when the value of σ is large (in other words, variance is large), and thus various measures are taken to lower the value of σ as much as possible.

A mask 3D effect (mask three-dimensional effect) is differences of calculation results of the amplitude and phase of diffracted light based on a Kirchhoff hypothesis on a thin structural object from the amplitude and phase of diffracted light generated from the mask pattern of an actual mask having a three-dimensional structure. The mask pattern (for example, a line or a line part of a space pattern) is a three-dimensional structure having a thickness of 100 nm approximately, depending on the kind of the mask. Due to the thickness, the amplitude and phase of diffracted light generated from the mask pattern are different from an amplitude and a phase calculated based on the Kirchhoff hypothesis in an optical diffracting theory (steps on a diffracting surface are ignored). What is called electromagnetic field analysis needs to be performed to correctly evaluate the amplitude and phase differences due to a mask three-dimensional effect. The mask three-dimensional effect is a conventionally existing phenomenon but has become significant along with pattern miniaturization, and its influence on lithography can no longer be ignored. A mask is synonymous with a reticle, and a mask pattern is synonymous with a reticle pattern.

An inter-pattern best focus difference is a phenomenon that multiple kinds of patterns have different best focus positions when the patterns exist on the same mask. The inter-pattern best focus difference is mainly caused by the wavefront aberration of a projection optical system of an exposure apparatus, the mask three-dimensional effect, and a thickness effect of a resist. The CD of each pattern is least likely to be affected by a focus difference near best focus of the pattern. Thus, with a smaller best focus difference, influence of focus in a view as a whole is smaller, and accordingly, excellent CDU is obtained.

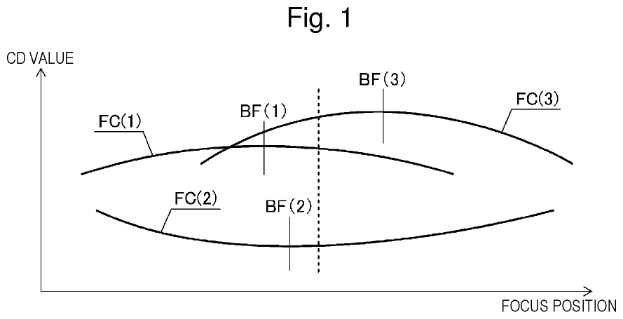

FIG. 1 is a graph illustrating an exemplary inter-pattern best focus difference. The horizontal axis represents the focus position, and the vertical axis represents the CD value. A characteristic curve representing the relation between focus and the CD as in FIG. 1 is referred to as a focus curve. In this example, focus curves FC(1), FC(2), and FC(3) of a pattern (1), a pattern (2), and a pattern (3) are illustrated. BF(1), BF(2), and BF(3) in FIG. 1 indicate best focus positions of the patterns (1), (2), and (3), respectively.

The best focus positions of all patterns are desirably at one place (for example, a dotted line in FIG. 1). Best-focus control of patterns can be performed by adjusting the central wavelength of a laser beam. When the central wavelength is changed, a 00 aberration in a Zernike wavefront aberration occurs. The 00 aberration provides different phase errors to diffracted light passing through different numerical apertures (NA), thus generating different focus difference amounts for different patterns.

### 2. Overview of Exposure System According to Comparative Example

2.1 Configuration

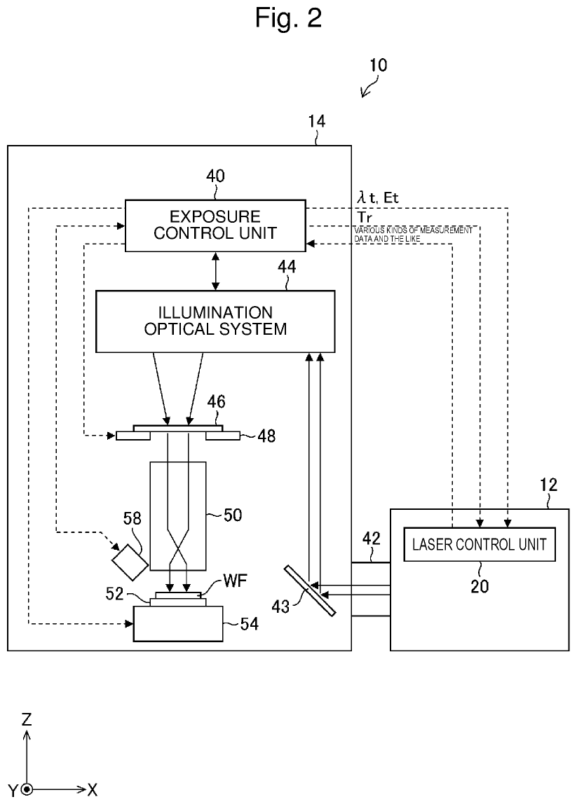

FIG. 2 schematically illustrates the configuration of an exposure system according to a comparative example. The comparative example of the present disclosure is an example that the applicant recognizes as known only by the applicant, but is not a publicly known example that is recognized by the applicant. The exposure system 10 includes a laser apparatus 12 and an exposure apparatus 14. The laser apparatus 12 is a variable-wavelength narrow-band oscillation ArF laser apparatus including a laser control unit 20, a non-illustrated laser chamber, and a non-illustrated line narrowing module.

The exposure apparatus 14 includes an exposure control unit 40, a beam delivery unit (BDU) 42, a high reflective mirror 43, an illumination optical system 44, a reticle 46, a reticle stage 48, a projection optical system 50, a wafer holder 52, a wafer stage 54, and a focus sensor 58.

The wafer holder 52 holds a wafer WF. The illumination optical system 44 is an optical system through which a pulse laser beam is guided to the reticle 46. The illumination optical system 44 shapes the laser beam into a scanning beam having a substantially rectangular shape and uniform light intensity distribution. In addition, the illumination optical system 44 controls the incident angle of the laser beam on the reticle 46. The projection optical system 50 images a reticle pattern on the wafer WF. The focus sensor 58 measures the height of a wafer surface.

The exposure control unit 40 is connected to the reticle stage 48, the wafer stage 54, and the focus sensor 58. The exposure control unit 40 is also connected to the laser control unit 20. Each of the exposure control unit 40 and the laser control unit 20 is configured as a non-illustrated processor and includes a storage device such as a memory. The storage device may be mounted on the processor.

2.2 Operation

The exposure control unit 40 controls movement of the wafer stage 54 in a Z axial direction to correct a focus position in a wafer height direction (the Z axial direction) based on the height of the wafer WF, which is measured by the focus sensor 58.

By a step-and-scan scheme, the exposure control unit 40 transmits control parameters of a target laser beam to the laser control unit 20 and controls the reticle stage 48 and the wafer stage 54 while transmitting a light emission trigger signal Tr to perform scanning exposure of an image of the reticle 46 to the wafer WF. The control parameters of a target laser beam include, for example, a target wavelength λt and a target pulse energy Et. Note that the phrase “target laser beam” means “target pulse laser beam”. “Pulse laser beam” is simply written as “laser beam” in some cases.

The laser control unit 20 controls a selection wavelength of the line narrowing module such that the wavelength λ of a pulse laser beam emitted from the laser apparatus 12 becomes equal to the target wavelength λt. The laser control unit 20 also controls excitation intensity such that the pulse energy E of the pulse laser beam becomes equal to the target pulse energy Et. Accordingly, the laser control unit 20 causes emission of the pulse laser beam in accordance with the light emission trigger signal Tr. In addition, the laser control unit 20 transmits, to the exposure control unit 40, various kinds of measurement data of the pulse laser beam emitted in accordance with the light emission trigger signal Tr. The various kinds of measurement data include, for example, the wavelength λ and the pulse energy E.

2.3 Exemplary Exposure Operation on Wafer

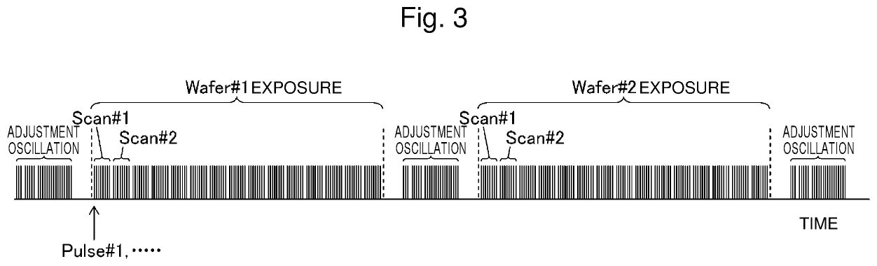

FIG. 3 illustrates an exemplary output pattern of the light emission trigger signal Tr transmitted from the exposure control unit 40 to the laser control unit 20. In the example illustrated in FIG. 3, an actual exposure pattern starts, after adjustment oscillation is performed for each wafer WF. Specifically, the laser apparatus 12 first performs the adjustment oscillation and then performs burst operation for first wafer exposure (Wafer #1) after a predetermined time interval.

The adjustment oscillation is oscillation with emission of an adjustment pulse laser beam but no irradiation of the wafer WF with the pulse laser beam. The adjustment oscillation is performed under a predetermined condition until the laser is stabilized in a state in which exposure is possible, and is performed before lot of wafer production. A pulse laser beam is emitted at a predetermined frequency of, for example, several hundreds Hz to several kHz approximately. In wafer exposure, it is typical to perform burst operation that repeats a burst duration and an oscillation stop duration. The burst operation is performed in the adjustment oscillation as well.

In FIG. 3, each interval in which pulses are closely spaced is the burst duration in which the pulse laser beam is continuously emitted for a predetermined duration. In FIG. 3, each interval in which no pulse exists is the oscillation stop duration. Note that, in the adjustment oscillation, the length of each continuous emission duration of pulses does not need to be constant, but continuous emission operation may be performed in continuous emission durations with different lengths for adjustment. After the adjustment oscillation is performed, followed by a relatively large time interval, the first wafer exposure (Wafer #1) is performed at the exposure apparatus 14.

The laser apparatus 12 stops oscillation during a step in exposure by the step-and-scan scheme and emits a pulse laser beam in accordance with the interval of the light emission trigger signal Tr during scanning. Such a pattern of laser oscillation is referred to as a burst oscillation pattern.

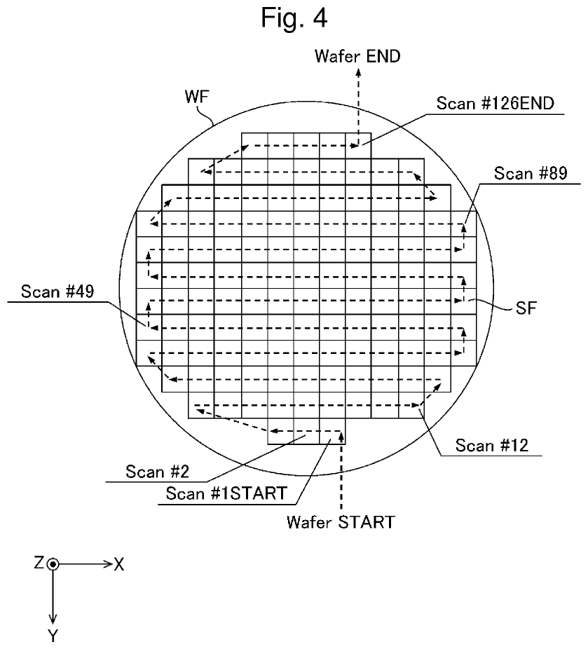

FIG. 4 illustrates an exemplary exposure pattern of step-and-scan exposure on the wafer WF. Each of a plurality of rectangular regions illustrated in the wafer WF in FIG. 4 is a scanning field SF. The scanning field SF is an exposure region of one scanning exposure and also referred to as a scanning region. As illustrated in FIG. 4, wafer exposure is performed by dividing the wafer WF into a plurality of exposure regions (scanning fields) of a predetermined size and performing scanning exposure in each exposure region in a duration between start (Wafer START) and end (Wafer END) of the wafer exposure.

Specifically, the wafer exposure repeats steps such as the first scanning exposure (Scan #1) in a first predetermined exposure region of the wafer WF and the second scanning exposure (Scan #2) in a second predetermined exposure region. During one scanning exposure, a plurality of pulse laser beams (Pulse #1, Pulse #2, . . . ) can be continuously emitted from the laser apparatus 12. After the scanning exposure (Scan #1) ends in the first predetermined exposure region, followed by a predetermined time interval, the scanning exposure (Scan #2) is performed in the second predetermined exposure region. When such scanning exposure is sequentially repeated and completed for all exposure regions of the first wafer WF, the adjustment oscillation is performed again and then wafer exposure (Wafer #2) of the second wafer WF is performed.

The step-and-scan exposure is performed in an order illustrated with dashed line arrows in FIG. 4, namely, Wafer START→Scan #1→Scan #2→ . . . →Scan #126→Wafer END. Each wafer WF is an example of a “semiconductor substrate” or a “photosensitive substrate” in the present disclosure.

2.4 Relation Between Scanning Field and Static Exposure Area

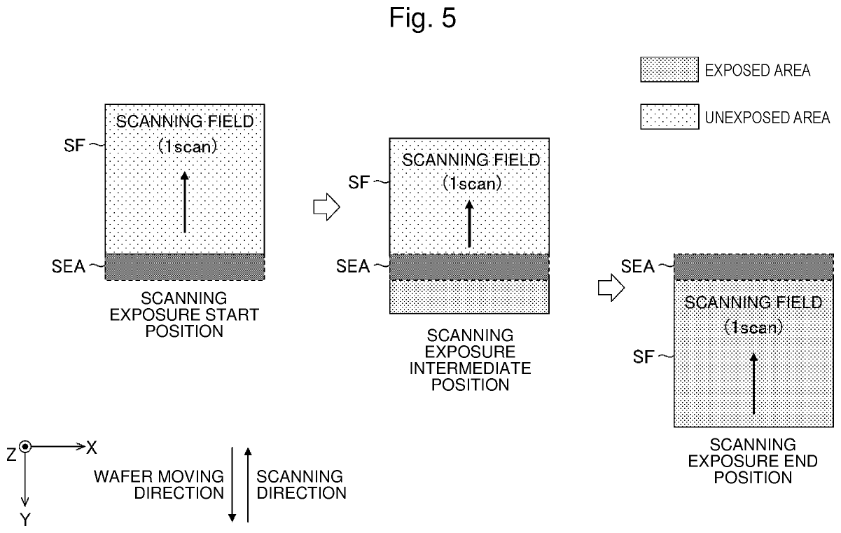

FIG. 5 illustrates the relation between one scanning field SF on the wafer WF and a static exposure area SEA. The static exposure area SEA is a beam irradiation region having a substantially rectangular shape and substantially uniform light intensity distribution and used for scanning exposure in the scanning field SF. Exposure is performed as the reticle 46 is irradiated with a substantially rectangular and substantially uniform scanning beam shaped through the illumination optical system 44 while the reticle 46 and the wafer WF are moved in mutually different directions along a short axial direction of the scanning beam (in this example, a Y axial direction) in accordance with a scaling-down ratio of the projection optical system 50. Accordingly, each scanning field on the wafer WF is subjected to scanning exposure to a reticle pattern. The static exposure area SEA can be understood as an area in which collective exposure by a scanning beam is possible.

In FIG. 5, a direction toward the negative Y axial direction side in the upward longitudinal direction is a scanning direction, and a direction toward the positive Y axial direction side is a wafer moving direction. A direction (X axial direction) parallel to the sheet of FIG. 5 and orthogonal to the Y axial direction is referred to as a scanning width direction. The size of each scanning field SF on the wafer WF is, for example, 33 mm in the Y axial direction and 26 mm in the X axial direction.

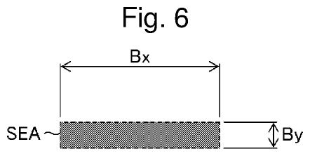

FIG. 6 is an explanatory diagram of the static exposure area SEA. When Bx represents the length of the static exposure area SEA in the X axial direction and By represents the width of the static exposure area SEA in the Y axial direction, Bx corresponds to the size of each scanning field SF in the X axial direction and By is sufficiently smaller than the size of each scanning field SF in the Y axial direction. The width By of the static exposure area SEA in the Y axial direction is referred to as an N slit. The number N_{SL} of pulses to which resist on the wafer WF is exposed is given by an expression below.

N_{SL}=(By/Vy)·f

Vy: scanning speed of the wafer in the Y axial direction

f: laser repetition frequency (Hz)

2.5 Problem

As described with reference to FIG. 1, for example, in a case of exposure near the best focus position of the pattern (1) when the inter-pattern best focus difference exists due to aberrations and the mask three-dimensional effect, the focus curve FC(1) of the pattern (1) has a gentle slope and thus influence of the focus position is small. However, the focus curve FC(3) of the pattern (3) has a steep slope, and the CD largely varies as the focus position varies. Thus, the CDU as a whole is not desirable. Furthermore, the CD of the pattern (3) is potentially shifted from a target value.

### 3. Embodiment 1

3.1 Overview of Lithography System

3.1.1 Configuration

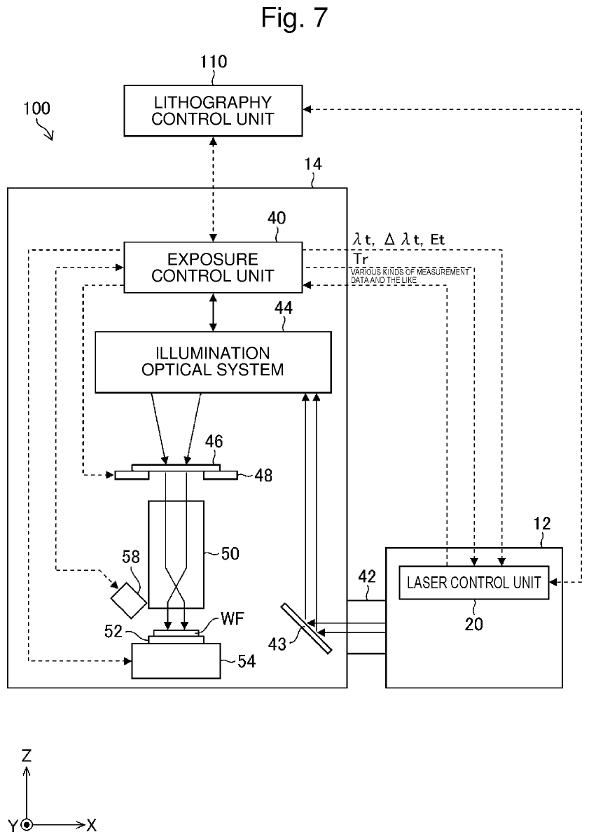

FIG. 7 illustrates an exemplary configuration of a lithography system 100 according to Embodiment 1. Description will be made on the difference of the configuration illustrated in FIG. 7 from the configuration illustrated in FIG. 2. The lithography system 100 illustrated in FIG. 7 includes a lithography control unit 110 in addition to the configuration illustrated in FIG. 2, and data transmission-reception lines are additionally provided between the lithography control unit 110 and the exposure control unit 40 and between the lithography control unit 110 and the laser control unit 20.

The lithography system 100 includes the laser apparatus 12, the exposure apparatus 14, and the lithography control unit 110. The lithography control unit 110 is configured as a non-illustrated processor. The lithography control unit 110 includes a storage device such as a memory. The processor may include the storage device. The lithography control unit 110 includes a calculation program that calculates, based on a pure (Fourier) imaging optical theory, optimum settings of the exposure apparatus 14 by using a mathematical method such as linear or non-linear optimization with different settings of the exposure apparatus 14 and different laser-beam control parameters (for example, wavelength). The calculation program incorporates a lithography simulation program including an electromagnetic field analysis function for a reticle pattern. Examples of parameters related to settings of the exposure apparatus 14 include the NA of each lens of the projection optical system 50, the illumination 6 of the illumination optical system 44, and a ring belt ratio.

3.1.2 Operation

The lithography control unit 110 uses the calculation program incorporating the lithography simulation program including an electromagnetic field analysis function for a reticle pattern, calculates, for each combination of multiple kinds of patterns (k) of a reticle pattern, an optimum wavelength λb with which the best focus positions of the patterns are closest to one another (in other words, have minimum dispersion), and stores data of the optimum wavelength λb in a file B in the lithography control unit 110. Note that the index number “k” in a pattern (k) identifies the kind of the pattern and is an integer of one to three in the example illustrated in FIG. 1.

The exposure control unit 40 reads, from the file B, data of the optimum wavelength λb corresponding to a scanning beam SB to be described later and the position of each pattern and calculates the target wavelength λt for each scanning field SF and each pulse based on the data of the file B. The exposure control unit 40 transmits laser-beam control parameter values (the target wavelength λt, a target spectrum line width Δλt, and the target pulse energy Et) of each pulse to the laser apparatus 12.

The following exposure operation may be the same as that of the exposure system 10 in FIG. 2. In addition, the spectrum line width Δλ of each pulse can be varied by, for example, controlling a delay time Δt between synchronization timings of an oscillator and an amplifier of the laser apparatus 12, which will be described later, for the pulse.

3.2 Exemplary Laser Apparatus

3.2.1 Configuration

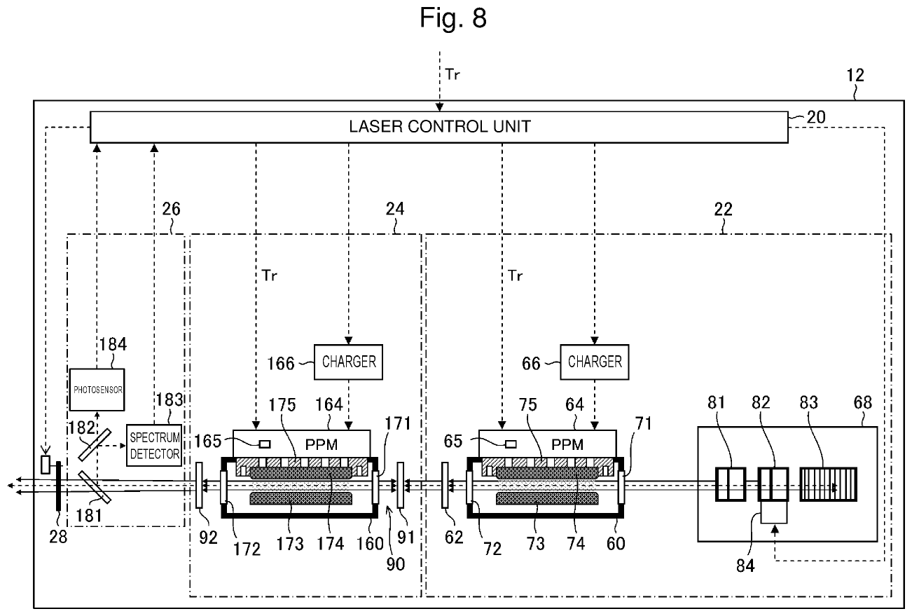

FIG. 8 illustrates an exemplary configuration of the laser apparatus 12. The laser apparatus 12 illustrated in FIG. 8 is a line narrowing ArF laser apparatus including the laser control unit 20, the oscillator 22, the amplifier 24, a monitor module 26, and a shutter 28. The oscillator 22 includes a chamber 60, an output coupling mirror 62, a pulse power module (PPM) 64, a charger 66, and a line narrowing module (LNM) 68.

The chamber 60 includes windows 71 and 72, a pair of electrodes 73 and 74, and an electrically insulating member 75. The PPM 64 includes a switch 65 and a non-illustrated charging capacitor and is connected to the electrode 74 via feed-through of the electrically insulating member 75. The electrode 73 is connected to the chamber 60 that is grounded. The charger 66 charges the charging capacitor of the PPM 64 in accordance with a command from the laser control unit 20.

The line narrowing module 68 and the output coupling mirror 62 constitute an optical resonator. The chamber 60 is disposed such that a discharge region of the pair of electrodes 73 and 74 is disposed on the optical path of the resonator. The output coupling mirror 62 is coated with a multi-layered film that reflects part of a laser beam generated in the chamber 60 and transmits other part of the laser beam.

The line narrowing module 68 includes two prisms 81 and 82, a grating 83, and a rotation stage 84 that rotates the prism 82. The line narrowing module 68 changes the incident angle of a pulse laser beam on the grating 83 by rotating the prism 82 by using the rotation stage 84, and accordingly, controls the oscillation wavelength of the pulse laser beam. The rotation stage 84 may include a piezoelectric element capable of performing high-speed response so that response to each pulse is possible.

The amplifier 24 includes an optical resonator 90, a chamber 160, a PPM 164, and a charger 166. The configurations of the chamber 160, the PPM 164, and the charger 166 are the same as the configurations of the corresponding elements of the oscillator 22. The chamber 160 includes windows 171 and 172, a pair of electrodes 173 and 174, and an electrically insulating member 175. The PPM 164 includes a switch 165 and a non-illustrated charging capacitor.

The optical resonator 90 is a Fabry-Perot optical resonator constituted by a rear mirror 91 and an output coupling mirror 92. The rear mirror 91 partially reflects part of a laser beam and transmits other part of the laser beam. The output coupling mirror 92 partially reflects part of a laser beam and transmits another part of the laser beam. The reflectance of the rear mirror 91 is, for example, 80% to 90%. The reflectance of the output coupling mirror 92 is, for example, 10% to 30%.

The monitor module 26 includes beam splitters 181 and 182, a spectrum detector 183, and a photosensor 184 configured to detect pulse energy E of a laser beam. The spectrum detector 183 may be, for example, an etalon spectrometer. The photosensor 184 may be, for example, a photodiode.

3.2.2 Operation

When having received data of the target wavelength λt, the spectrum line width Δλt, and the target pulse energy Et from the exposure control unit 40, the laser control unit 20 controls the rotation stage 84 of the LNM 68 such that an emission wavelength becomes equal to the target wavelength λt, controls a scheme to be described later such that the target spectrum line width Δλt is obtained, and controls at least the charger 166 of the amplifier 24 such that the target pulse energy Et is obtained.

When having received the light emission trigger signal Tr from the exposure control unit 40, the laser control unit 20 provides a trigger signal to each of the switch 165 of the PPM 164 and the switch 65 of the PPM 64 so that discharge occurs when a pulse laser beam emitted from the oscillator 22 enters a discharge space of the chamber 160 of the amplifier 24. As a result, the pulse laser beam emitted from the oscillator 22 is subjected to amplified oscillation at the amplifier 24. The amplified pulse laser beam is sampled by the beam splitter 181 of the monitor module 26 to measure the pulse energy E, the wavelength λ, and the spectrum line width Δλ.

The laser control unit 20 acquires data of the pulse energy E, the wavelength λ, and the spectrum line width Δλ measured by using the monitor module 26. Then, the laser control unit 20 controls the charging voltage of the charger 166, the discharge timings of the oscillator 22 and the amplifier 24 and the oscillation wavelength of the oscillator 22, so that the difference between the pulse energy E and the target pulse energy Et, the difference between the wavelength λ and the target wavelength λt, and the difference between the spectrum line width Δλ and the target spectrum line width Δλt each become closer to zero.

The laser control unit 20 can control the pulse energy E, the wavelength λ, and the spectrum line width Δλ for each pulse. The spectrum line width Δλ of the pulse laser beam emitted from the laser apparatus 12 can be controlled by controlling the delay time Δt between the discharge timings of the chamber 60 of the oscillator 22 and the chamber 160 of the amplifier 24.

The pulse laser beam having transmitted through the beam splitter 181 of the monitor module 26 enters the exposure apparatus 14 through the shutter 28.

3.2.3 Other

Although the optical resonator 90 is a Fabry-Perot resonator in the example illustrated in FIG. 8, the amplifier may include a ring resonator.

3.3 Exemplary Focus Curve of Reticle Pattern

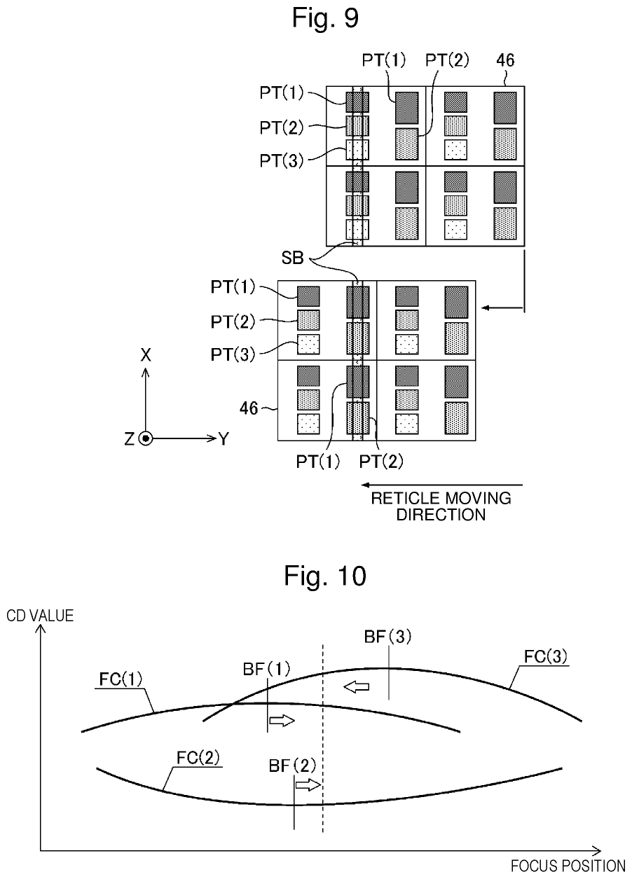

FIG. 9 is a plan view schematically illustrating an exemplary reticle pattern. The upper part of FIG. 9 illustrates an exemplary positional relation between the reticle 46 and the scanning beam SB at a time point t1 during scanning exposure, and the lower part of FIG. 9 illustrates an exemplary positional relation between the reticle 46 and the scanning beam SB at a time point t2 (>t1). The reticle moves in the direction from right to left in FIG. 9 (direction toward the negative side in the Y axial direction). The scanning beam SB moves relative to the reticle 46 in a direction toward the positive side in the Y axial direction.

Various patterns exist on the reticle 46. FIG. 9 illustrates exemplary arrangement of three kinds of pattern regions. In FIG. 9, PT(1), PT(2), and PT(3) represent the patterns (1), (2), and (3), respectively. Note that the circumferential region other than the patterns (1), (2), and (3) on the reticle surface may be a no-pattern region or may include a pattern (4) (fourth pattern). The pattern (4) may have a line width larger than those of the patterns (1), (2), and (3) or may have a low requested accuracy (wide allowable range) for the line width.

In the example illustrated in FIG. 9, the reticle 46 corresponding to one scanning field SF is divided into four areas, and each divided area corresponds to a circuit pattern of one chip. The divided areas have common arrangement of the patterns (1), (2), and (3).

The reticle 46 includes, from the left in FIG. 9, the region of a first column pattern group in which the three kinds of patterns (1), (2), and (3) are arranged in the X axial direction, the region of a second column pattern group in which the two kinds of patterns (1) and (2) are arranged in the X axial direction, the region of a third column pattern group in which the three kinds of patterns (1), (2), and (3) are arranged in the X axial direction, and the region of a fourth column pattern group in which the two kinds of patterns (1) and (2) are arranged in the X axial direction.

This example includes the first column pattern group and the third column pattern group each consisting of the combination of the three kinds of patterns (1), (2), and (3), and the second column pattern group and the fourth column pattern group each consisting of the combination of the two kinds of patterns (1) and (2), but the combination of patterns, the form of arrangement, the number of columns of pattern groups, and the like are not limited to those in the example illustrated in FIG. 9.

The upper part of FIG. 9 illustrates a state in which the first column pattern group is irradiated with the scanning beam SB, and the lower part of FIG. 9 illustrates a state in which the second column pattern group is irradiated with the scanning beam SB. The pattern group of each column in which multiple kinds of patterns are arranged in the X axial direction includes a mixture of two or more kinds of patterns in a region that is collectively irradiated with the scanning beam SB.

FIG. 10 exemplarily illustrates the focus curves of the patterns (1) to (3) in case 1 illustrated in the upper part of FIG. 9. The best focus position BF(1) is understood from the focus curve FC(1) of the pattern (1) illustrated in FIG. 10. Similarly, the best focus positions BF(2) and BF(3) are understood from the focus curve FC(2) of the pattern (2) and the focus curve FC(3) of the pattern (3), respectively.

The lithography control unit 110 of Embodiment 1 calculates the optimum wavelength λb with which the best focus position BF(1) of the pattern (1), the best focus position BF(2) of the pattern (2), and the best focus position BF(3) of the pattern (3) approach a focus position illustrated with a dotted line in FIG. 10. The focus position illustrated with the dotted line in FIG. 10 corresponds to the average value of the best focus positions BF(1), BF(2), and BF(3).

The best focus position BF(k) of the pattern (k) is the position of focus at which the value of the CD has an extreme value on the focus curve FC(k). When the wavelength λ of a pulse laser beam is changed, each focus curve FC(k) changes and the best focus position BF(k) changes as well. The wavelength λ with which dispersion of BF(k) of multiple kinds of patterns (k) is minimum can be obtained by calculating BF(k) with different values of the wavelength λ. The best focus position BF(k) is an example of a “best focus position corresponding to each of multiple kinds of patterns” in the present disclosure.

Dispersion is an indicator of the degree of dispersion (degree of variance) of data and can be obtained by, for example, calculating the mean square of deviation as defined in statistics. Note that the dispersion may be calculated with weights in accordance with patterns.

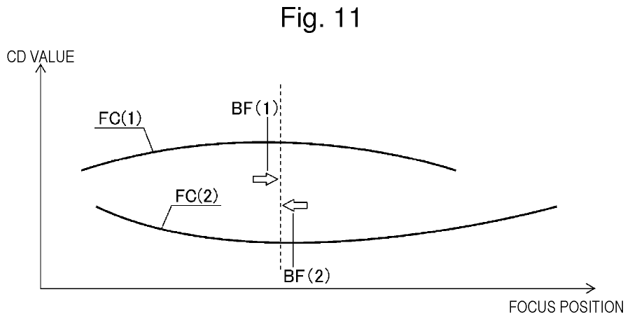

FIG. 11 exemplarily illustrates focus curves of the patterns (1) and (2) in case 2 illustrated in the lower part of FIG. 9. The lithography control unit 110 calculates, for the combination of the patterns (1) and (2), the optimum wavelength λb with which the best focus position BF(1) understood from the focus curve FC(1) and the best focus position BF(2) understood from the focus curve FC(2) approach the position of a dotted line in the drawing. The focus position illustrated with the dotted line in FIG. 11 corresponds to the average value of the best focus positions BF(1) and BF(2).

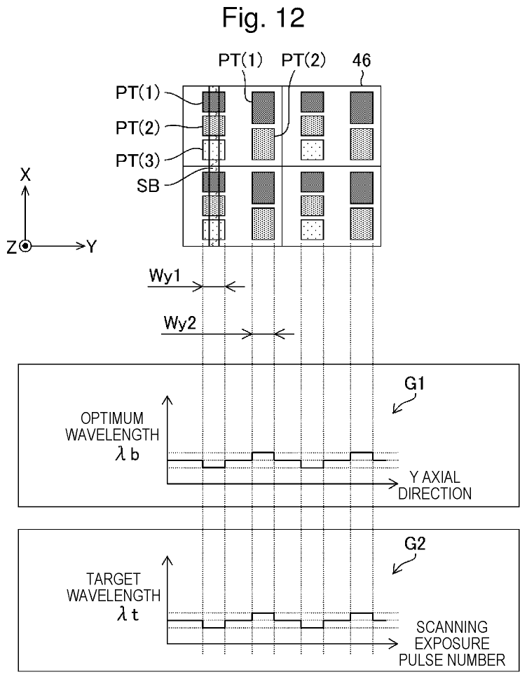

FIG. 12 illustrates an exemplary relation among the reticle pattern, the optimum wavelength λb, and the target wavelength λt. The upper part of FIG. 12 is a plan view schematically illustrating the relation between the reticle pattern and the scanning beam SB. In this example, a state in which the first column pattern group of the reticle 46 is irradiated with the scanning beam SB is illustrated. The scanning beam SB performs scanning movement relative to the reticle 46 toward the positive side in the Y axial direction.

Wy1 represents the widths of the regions of the patterns (1), (2), and (3) in the first column pattern group of the reticle 46 in the Y axial direction, and Wy2 represents the widths of the regions of the patterns (1) and (2) in the second column pattern group in the Y axial direction. The beam width (By width) of the scanning beam SB in the Y axial direction may be smaller than the values of Wy1 and Wy2.

A graph G1 representing the relation between the position in the Y axial direction and the optimum wavelength λb within one scanning is illustrated in a frame in the middle part of FIG. 12. A graph G2 representing the target wavelength λt for each scanning exposure pulse corresponding to the position in the Y axial direction within one scanning is illustrated in a frame in the lower part of FIG. 12. FIG. 12 illustrates an example in which the exposure control unit 40 reads data of the file B produced by the lithography control unit 110, uses the value of the optimum wavelength λb corresponding to the region of each combination of the patterns (1) to (3), and directly transmits the value to the laser control unit 20 as the target wavelength λt. Transmitting the target wavelength λt to the laser control unit 20 is an example of “instructing the laser apparatus about a target wavelength of the pulse laser beam” in the present disclosure.

3.4 Exemplary Contents of Processing by Lithography Control Unit

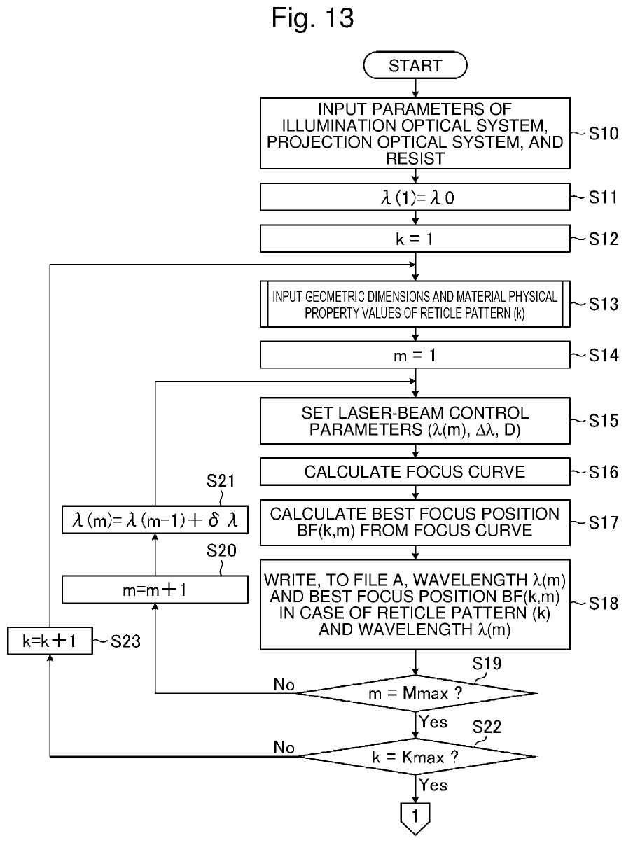

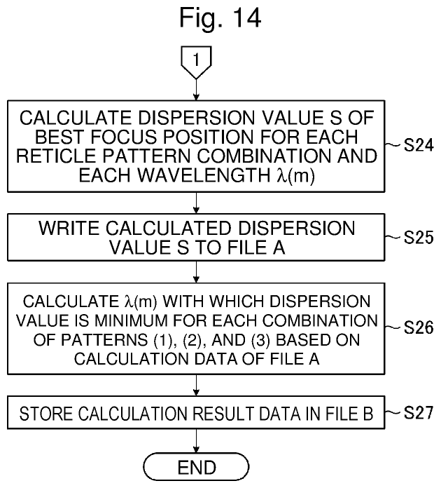

FIGS. 13 and 14 are flowcharts illustrating exemplary processing performed by the lithography control unit 110 of Embodiment 1. Steps illustrated in FIGS. 13 and 14 are implemented through execution of a program by the processor that functions as the lithography control unit 110.

At step S10, the lithography control unit 110 receives input of data of parameters including parameters of the illumination optical system 44, parameters of the projection optical system 50 including wavefront aberration, and parameters of resist.

Examples of the parameters of the illumination optical system 44 include the value of 6 and an illumination shape. Examples of the parameters of the projection optical system 50 include lens data, lens NA, and wavefront aberration. Examples of the parameters of resist include sensitivity.

At step S11, the lithography control unit 110 sets λ0 to the wavelength λ(1). The wavelength λ0 may be a predetermined value. At step S12, the lithography control unit 110 sets an index k corresponding to a pattern number indicating the kind of a reticle pattern to the initial value of “1”.

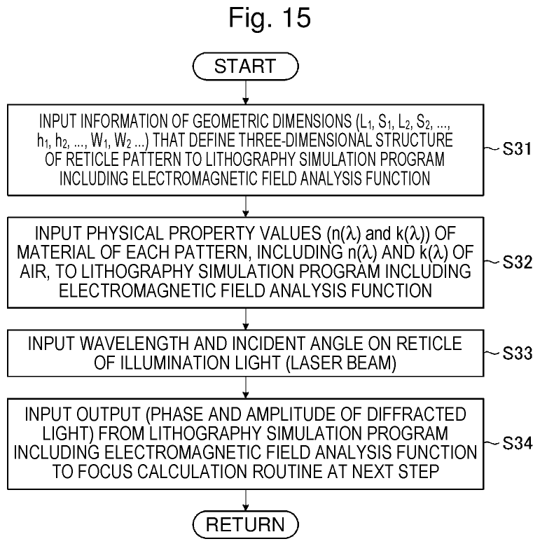

Then at step S13, the lithography control unit 110 receives input of geometric dimensions that define the three-dimensional structure of the reticle pattern (k) and information of physical property values of the material of the reticle pattern (k). Exemplary processing contents at step S13 will be described later with reference to FIG. 15.

At step S14, the lithography control unit 110 sets a wavelength index m to the initial value of “1”. Subsequently at step S15, the lithography control unit 110 sets initial values of laser-beam control parameters. The laser-beam control parameters may be, for example, the wavelength λ(m), the spectrum line width Δλ, and an exposure amount (dose) D. Note that the pulse energy E may be used in place of or in addition to the exposure amount D.

The relation between the exposure amount D and the pulse energy E on the wafer surface is expressed by an expression below.

D=T·E·NS_{L}/(Bx·By)

In the expression, T represents transmittance from the laser apparatus 12 to the wafer WF.

The expression can be rewritten as described below.

E=D·(Bx·By)/(T·N_{SL})

At step S16, the lithography control unit 110 calculates a focus curve FC(k,m) based on the input data. Specifically, the lithography control unit 110 calculates the focus curve FC(k,m) corresponding to the reticle pattern (k) and the wavelength λ(m) with given conditions in accordance with the calculation program.

At step S17, the lithography control unit 110 calculates a best focus position BF(k,m) from the focus curve FC(k,m) calculated at step S16.

At step S18, the lithography control unit 110 writes, to a file A, the wavelength λ(m) and the best focus position BF(k,m) in a case of the reticle pattern (k) and the wavelength λ(m).

Then at step S19, the lithography control unit 110 determines whether the value of the index m is equal to Mmax. The value Mmax is the upper limit value (maximum value) of the value of m and is a predetermined value.

When the result of the determination at step S19 is “No”, the lithography control unit 110 proceeds to step S20 and increments the value of m. Then at step S21, the lithography control unit 110 changes the wavelength λ(m) in accordance with a formula λ(m)=λ(m−1)+δλ and returns to step S15. The value δλ is a change amount (step amount) of the wavelength when the wavelength is changed. The lithography control unit 110 changes the wavelength by the predetermined change amount δλ. Until the value of m reaches Mmax, the processing at steps S15 to S21 is performed a plurality of times with different values of the wavelength λ(m).

When the result of the determination at step S19 is “Yes”, the lithography control unit 110 proceeds to step S22. At step S22, the lithography control unit 110 determines whether the value of the index k is equal to Kmax. The value Kmax is the upper limit value (maximum value) of the value of k and is a predetermined value. In the example illustrated in FIG. 9, Kmax is “3”.

When the result of the determination at step S22 is “No”, the lithography control unit 110 proceeds to step S23, increments the value of k, and returns to step S13. Until the value of k reaches Kmax, steps S13 to S23 are performed a plurality of times with different values of k.

When the result of the determination at step S22 is “Yes”, the lithography control unit 110 proceeds to step S24 in FIG. 14.

At step S24, the lithography control unit 110 calculates a dispersion value S of the best focus positions for each combination of the reticle patterns and the wavelength λ(m).

Then at step S25, the lithography control unit 110 writes the dispersion value S as the result of the calculation at step S24 to the file A.

Then at step S26, the lithography control unit 110 calculates λ(m) with which the dispersion value is minimum for each combination of the patterns (1), (2), and (3) based on the calculation data of the file A.

Then at step S27, the lithography control unit 110 stores data of the result of the calculation at step S26 in the file B.

After step S27, the lithography control unit 110 ends the flowcharts in FIGS. 13 and 14.

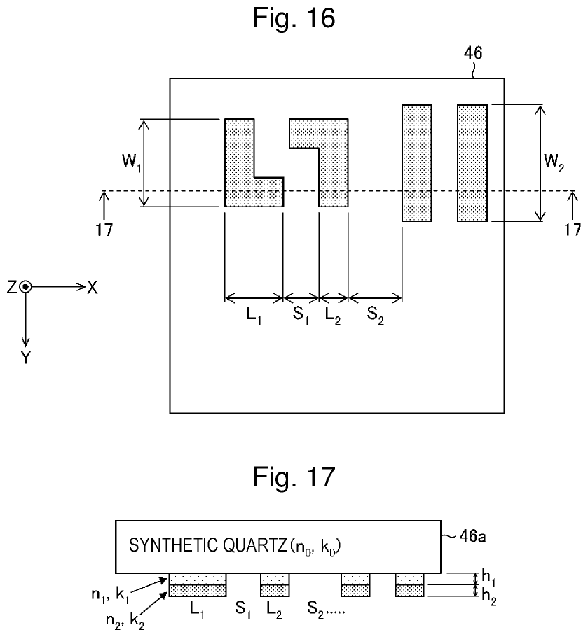

FIG. 15 is a flowchart illustrating exemplary processing contents applied to step S13 in FIG. 13. At step S31, the lithography control unit 110 inputs information of the geometric dimensions that define the three-dimensional structure of the reticle pattern to the lithography simulation program including an electromagnetic field analysis function. Examples of the geometric dimensions include a width Lk of each line part of each pattern in the X axial direction, a width Sk of a space part of each pattern in the X axial direction, a thickness hj of each layer of the three-dimensional structure of each pattern, and a width Wk of a line part of each pattern in the Y axial direction (refer to FIGS. 16 and 17). Note that the additional character “j” of the thickness hj indicates the layer number of a layer structure.

At step S32, the lithography control unit 110 inputs physical property values (n(λ) and k(λ)) of the material of each pattern, including the refractive index n(λ) and the extinction coefficient k(λ) of air, to the lithography simulation program including an electromagnetic field analysis function.

At step S33, the lithography control unit 110 receives input of information of the wavelength of illumination light (laser beam) and the incident angle of the illumination light on the reticle 46.

At step S34, the lithography control unit 110 inputs output (the phase and amplitude of diffracted light) of a calculation result by the lithography simulation program including an electromagnetic field analysis function to a focus calculation routine at the next step.

After step S34, the lithography control unit 110 ends the flowchart in FIG. 15 and returns to the main flow in FIG. 13. The method of calculating an optimum wavelength as a laser control parameter in accordance with the flowcharts in FIGS. 13 to 15 is an example of a “method of producing a laser control parameter” in the present disclosure.

FIG. 16 is a plan view schematically illustrating part of the reticle pattern. FIG. 17 is a cross-sectional view taken along line 17-17 in FIG. 16. Note that FIG. 17 illustrates a double-layer structure as an exemplary laminated structure of patterns, but the laminated structure of patterns of the reticle 46 may include three layers or more. A basal plate 46a of the reticle 46 may be made of, for example, synthetic quartz.

In FIG. 17, (n₀, k₀) indicates that the synthetic quartz has a refractive index of no and an extinction coefficient of k₀. The material of a first layer of the pattern illustrated in FIGS. 16 and 17 has a refractive index of n₁, an extinction coefficient of k₁, and a thickness of h₁. The material of a second layer of the pattern has a refractive index of n₂, an extinction coefficient of k₂, and a thickness of h₂. Each of L₁, S₁, L₂, S₂, . . . , h₁, h₂, . . . , W₁, W₂, . . . , as examples of the geometric dimensions, represents a dimension of an element in the three-dimensional structure of the pattern as illustrated in FIGS. 16 and 17.

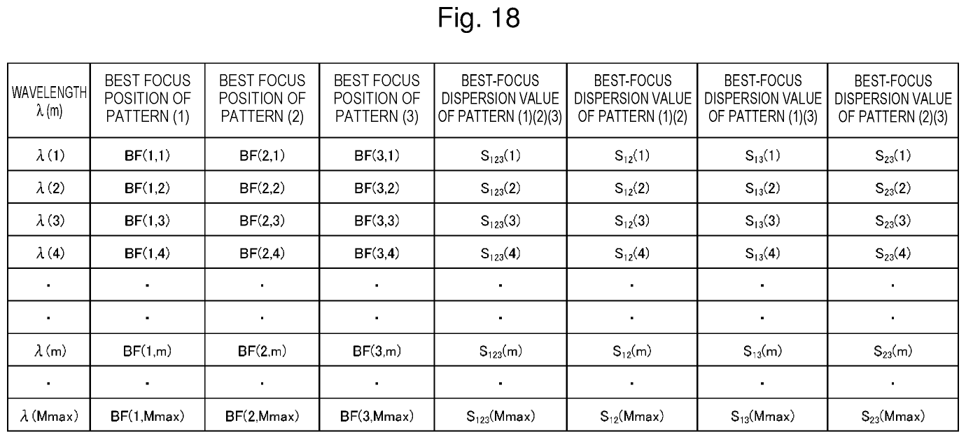

FIG. 18 is a table listing exemplary data stored in the file A. The file A stores a table of data of the best focus position for each wavelength λ(m) and each pattern and the best-focus dispersion value for each combination of multiple kinds of patterns. The file A is an example of a “first file” in the present disclosure.

Based on the data of the file A, a wavelength with which the best-focus dispersion value is minimum can be calculated for each combination of multiple kinds of patterns. In FIG. 18, the term “pattern (1) (2) (3)” represents a combination of the three kinds of patterns (1), (2), and (3).

The term “pattern (1) (2)” represents a combination of the two kinds of patterns (1) and (2). The term “pattern (1) (3)” represents a combination of the two kinds of patterns (1) and (3). The term “pattern (2) (3)” represents a combination of the two kinds of patterns (2) and (3).

For example, when S₁₂₃(3) is the minimum value in a data group {S₁₂₃(1), S₁₂₃(2), . . . , S₁₂₃(Mmax)} of the best-focus dispersion value S₁₂₃ for the combination of the pattern (1) (2) (3) in FIG. 18, the wavelength with which the dispersion value S₁₂₃ is minimum is λ(3). Similarly, when S₁₂(4) is the minimum value of the best-focus dispersion value S₁₂ for the combination of the pattern (1) (2), the wavelength with which the dispersion value S₁₂ is minimum is λ(4). When the minimum value of the best-focus dispersion value S₁₃ for the combination of the pattern (1) (3) is S₁₃(m), the wavelength with which the dispersion value S₁₃ is minimum is λ(m). When the minimum value of the best-focus dispersion value S₂₃ for the combination of the pattern (2) (3) is S₂₃(2), the wavelength with which the dispersion value S23 is minimum is λ(2).

In this manner, the wavelength (optimum wavelength λb) with which the best-focus dispersion value S is minimum can be obtained for each combination of patterns. Data as a collection of the correspondence between each combination of patterns and the optimum wavelength λb with which the best-focus dispersion value S is minimum is stored in the file B.

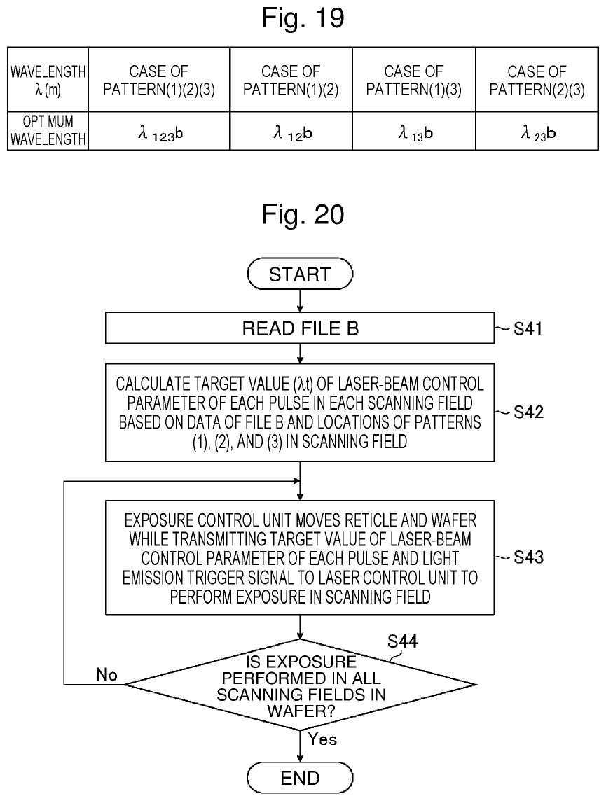

FIG. 19 is a table listing exemplary data stored in the file B. The file B stores a table of data of the optimum wavelength λb for each combination of patterns. In the example described with reference to FIG. 18, the optimum wavelength λ_{123b} for the combination of the pattern (1) (2) (3) is λ(3). In addition, the optimum wavelength λ_{12b} for the combination of the pattern (1) (2) is λ(4), the optimum wavelength λ_{13b} for the combination of the pattern (1) (3) is λ(m), and the optimum wavelength λ_{23b} for the combination of the pattern (2) (3) is λ(2). The file B is an example of a “second file” and a “file” in the present disclosure.

3.5 Exemplary Contents of Processing by Exposure Control Unit

FIG. 20 is a flowchart illustrating exemplary processing performed by the exposure control unit 40 of Embodiment 1. Steps illustrated in FIG. 20 are implemented through execution of a program by the processor that functions as the exposure control unit 40.

At step S41, the exposure control unit 40 reads data of the file B stored in the lithography control unit 110.

At step S42, the exposure control unit 40 calculates a target value (in this example, the target wavelength λt) of a laser-beam control parameter of each pulse in each scanning field SF based on the data of the file B and the locations of the patterns (1), (2), and (3) in the scanning field SF.

At step S43, the exposure control unit 40 moves the reticle 46 and the wafer WF while transmitting the target value of the laser-beam control parameter of each pulse and the light emission trigger signal Tr to the laser control unit 20 to perform exposure in the scanning field SF.

At step S44, the exposure control unit 40 determines whether exposure is performed in all scanning fields SF in the wafer WF. When the result of the determination at step S44 is “No”, the exposure control unit 40 returns to step S43. When the result of the determination at step S44 is “Yes”, the exposure control unit 40 ends the flowchart in FIG. 20.

3.6 Exemplary Contents of Processing by Laser Control Unit

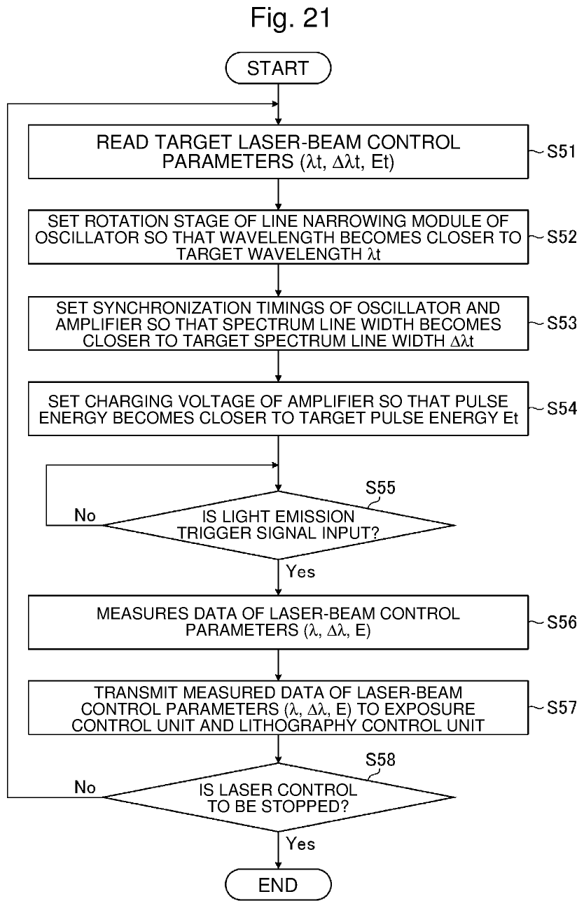

FIG. 21 is a flowchart illustrating exemplary processing performed by the laser control unit 20 of Embodiment 1. Steps illustrated in FIG. 21 are implemented through execution of a program by a processor that functions as the laser control unit 20.

At step S51, the laser control unit 20 reads data of the target laser-beam control parameters (λt, Δλt, and Et) transmitted from the exposure control unit 40.

At step S52, the laser control unit 20 sets the rotation stage 84 of the line narrowing module 68 of the oscillator 22 such that the wavelength λ of a pulse laser beam emitted from the laser apparatus 12 becomes closer to the target wavelength λt.

At step S53, the laser control unit 20 sets synchronization timings of the oscillator 22 and the amplifier 24 such that the spectrum line width Δλ of the pulse laser beam emitted from the laser apparatus 12 becomes closer to the target spectrum line width Δλt.

At step S54, the laser control unit 20 sets charging voltage of the amplifier 24 such that the pulse energy E becomes closer to the target pulse energy Et.

At step S55, the laser control unit 20 waits for input of the light emission trigger signal Tr and determines whether the light emission trigger signal Tr is input. When the light emission trigger signal Tr is not input, the laser control unit 20 repeats step S55. When the light emission trigger signal Tr is input, the laser control unit 20 proceeds to step S56.

At step S56, the laser control unit 20 measures data of the laser-beam control parameters by using the monitor module 26. The laser control unit 20 acquires data of the wavelength λ, the spectrum line width Δλ, and the pulse energy E through the measurement at step S56.

At step S57, the laser control unit 20 transmits the data of the laser-beam control parameters measured at step S56 to the exposure control unit 40 and the lithography control unit 110.

At step S58, the laser control unit 20 determines whether to stop laser control. When the result of the determination at step S58 is “No”, the laser control unit 20 returns to step S51. When the result of the determination at step S58 is “Yes”, the laser control unit 20 ends the flowchart in FIG. 21.

3.7 Effect

In the lithography system 100 according to Embodiment 1, the wavelength of a pulse laser beam is adjusted such that the inter-pattern best focus difference decreases for a combination of multiple kinds of patterns. According to Embodiment 1, it is possible to reduce the inter-pattern best focus difference due to the mask three-dimensional effect and improve the CDU.

3.8 Other

Although the above description is made on correction of the best focus difference due to the mask three-dimensional effect, the present embodiment is also applicable to correction of the inter-pattern best focus difference due to wavefront aberration of the projection optical system 50 and the inter-pattern best focus difference due to the resist thickness effect.

Embodiment 1 describes an example in which functions of the lithography control unit 110 and the exposure control unit 40 are separated, but the invention is not limited to the example and the exposure control unit 40 may include the function of the lithography control unit 110.

The calculation processes as illustrated in FIGS. 13 and 14 may be executed in advance by a computer on which the calculation program is installed, and the file B as illustrated in FIG. 19 may be stored in a storage unit of the lithography control unit 110 or the exposure control unit 40. The lithography control unit 110 may be a server configured to manage various parameters used for scanning exposure. The server may be connected to a plurality of exposure systems through a network. For example, the server is configured to perform the calculation processes as illustrated in FIGS. 13 and 14 and write the calculated values of the control parameters to the file B.

### 4. Embodiment 2

4.1 Configuration

The configuration of a lithography system according to Embodiment 2 may be the same as that in Embodiment 1.

4.2 Operation

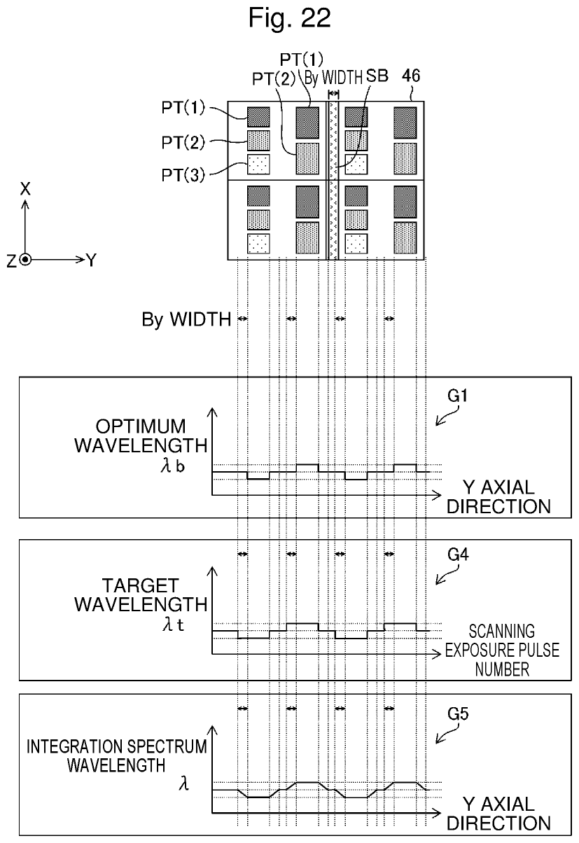

FIG. 22 illustrates an exemplary relation among the reticle pattern, the optimum wavelength λb, the target wavelength λt, and an integration spectrum wavelength λ in the lithography system according to Embodiment 2. Description will be made on the difference of FIG. 22 from FIG. 12. In FIG. 22, a graph G4 is illustrated in place of the graph G2 in FIG. 12. A graph G5 representing the integration spectrum wavelength λ of a scanning exposure pulse corresponding to the position in the Y axial direction within one scanning is illustrated in a frame in the lowermost part of FIG. 22.

During scanning exposure, the reticle 46 moves toward the negative side in the Y axial direction. The following description assumes that the scanning beam SB moves relative to the reticle 46 toward the positive side in the Y axial direction.

The graph G4 is changed from the graph G2 in FIG. 12 such that the value of the target wavelength λt is switched at a timing earlier on the negative side (near side) of boundary positions of the regions of the patterns (1) to (3) on the negative side in the Y axial direction by the beam width (By width) of the scanning beam SB in the Y axial direction. This corresponds to setting of the same target wavelength λt to a virtual expanded region obtained by expanding a boundary region of each pattern on the negative side in the Y axial direction from the boundary position of the region toward the negative side in the Y axial direction by a strip-shaped region equivalent to the By width.

Note that the scanning beam SB with which the reticle 46 is illuminated has, on the wafer WF, a size in accordance with magnification of the projection optical system 50 of the exposure apparatus 14. For example, when the magnification of the projection optical system 50 is ¼, the scanning beam SB with which the reticle 46 is illuminated has a size ¼ times larger on the wafer WF. A scanning field area on the reticle 46 is a scanning field SF having a size ¼ times larger on the wafer WF. The beam width (By width) of the scanning beam SB with which the reticle 46 is illuminated in the Y axial direction leads to the width By of the static exposure area SEA on the wafer WF in the Y axial direction.

The graph G5 representing the integration spectrum wavelength λ of each scanning exposure pulse corresponding to the position in the Y axial direction in one scanning field SF is illustrated in the frame in the lowermost part of FIG. 22.

When the target wavelength λt is set as illustrated in the graph G4, the integration spectrum wavelength λ is as illustrated in the graph G5 and the integration spectrum wavelength λ is maintained constant in the ranges of the regions of pattern groups in the first to fourth columns.

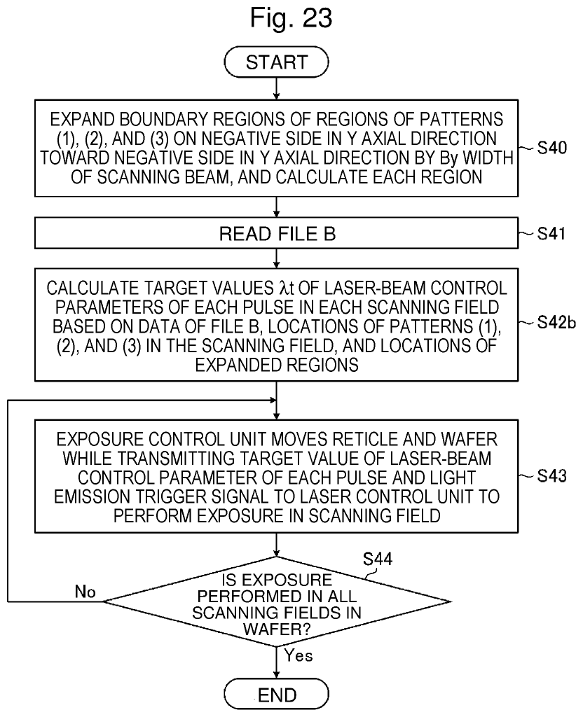

FIG. 23 is a flowchart illustrating exemplary processing performed by the exposure control unit 40 of Embodiment 2. Description will be made on the difference of the flowchart illustrated in FIG. 23 from that in FIG. 20. In the flowchart illustrated in FIG. 23, step S40 is added before step S41, and step S42b is included in place of step S42 in FIG. 20.

At step S40, the exposure control unit 40 expands the boundary regions of the regions of the patterns (1) to (3) on the negative side in the Y axial direction toward the negative side in the Y axial direction by the By width of the scanning beam SB and calculates expanded regions of the regions. In other words, the exposure control unit 40 moves the boundary position of each of the regions of the patterns (1) to (3) on the negative side in the Y axial direction by a distance corresponding to the beam width (By width) of the scanning beam SB to expand the range of the region toward the negative side in the Y axial direction by an amount equivalent to the By width, thereby changing the region to an expanded region. The boundary region equivalent to the By width, which is added on the negative side of each region in the Y axial direction is referred to as a “transition region”.

At step S42b, the exposure control unit 40 calculates the target values of the laser-beam control parameters of each pulse (in this example, at least the target wavelength λt) in each scanning field SF based on the data of the file B, the locations of the patterns (1), (2), and (3) in the scanning field SF, and the locations of the expanded regions. Processing at step S43 and later is the same as that in FIG. 20.

4.3 Effect

The wavelength λ of a pulse laser beam for exposure in each scanning field SF is the moving integration spectrum wavelength λ of the number N_{SL} of exposure pulses. According to Embodiment 2, the moving integration spectrum wavelength λ with which the regions of the patterns (1), (2), and (3) are irradiated is the optimum wavelength λb, and thus the patterns (1) to (3) can be exposed with the optimum wavelength λb.

### 5. Embodiment 3

5.1 Configuration

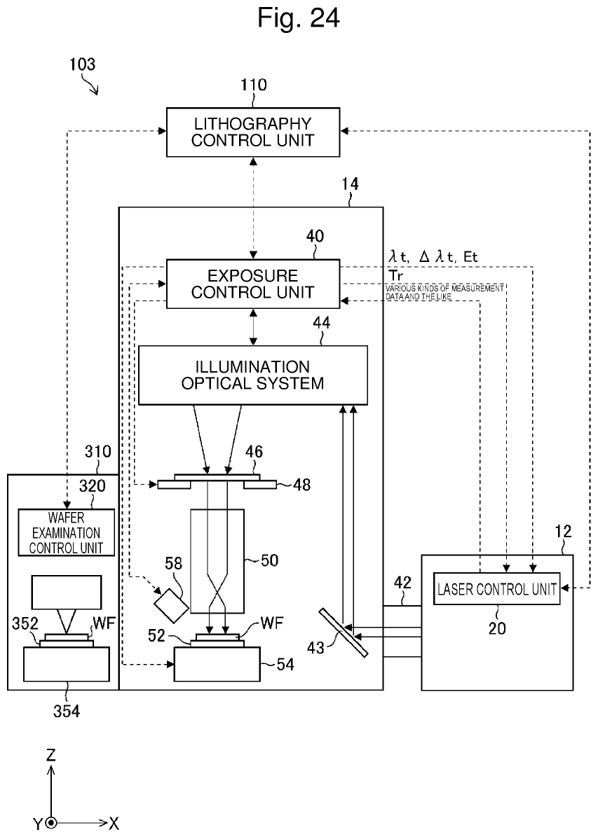

FIG. 24 illustrates an exemplary configuration of a lithography system 103 according to Embodiment 3. The lithography system 103 according to Embodiment 3 includes a wafer examination device 310 in addition to the configuration illustrated in FIG. 7. The other configuration may be the same as that in Embodiment 1. The wafer examination device 310 can perform CD, focus, and overlay measurement by irradiating the wafer WF with a laser beam and measuring reflected light or diffracted light of the laser beam. Alternatively, the wafer examination device 310 may be a high-resolution scanning electron microscope (SEM). The wafer examination device 310 includes a wafer examination control unit 320, a wafer holder 352, and a wafer stage 354. The wafer examination device 310 is an example of an “examination device” in the present disclosure.

The lithography control unit 110 is connected to a line through which data and the like are transmitted and received to and from the wafer examination control unit 320.

5.2 Operation

The lithography control unit 110 causes the wafer examination device 310 to examine the wafer WF subjected to exposure. The lithography control unit 110 links parameters with a pattern and a CD value at each place on the wafer WF, which are measured by the wafer examination device 310 and the wavelength λ and focus position F of a laser beam used for exposure at each place. The term “link” is synonymous with “associate” or “relate”. The exposure-completed wafer WF as a target of examination by the wafer examination device 310 is an example of an “exposure-completed semiconductor substrate” in the present disclosure.

The lithography control unit 110 calculates, based on a result of actual exposure of the wafer WF, the best focus position BF(k,m) for each pattern (k) from the focus curve of the wavelength λ(m) of the exposure and stores data in the file A as illustrate in FIG. 18.

The lithography control unit 110 calculates the best-focus dispersion value for each combination of the patterns (1) to (3) and the wavelength λ(m) and appends the result of the calculation to the file A as illustrated in FIG. 18. The following process is the same as that in Embodiment 1.

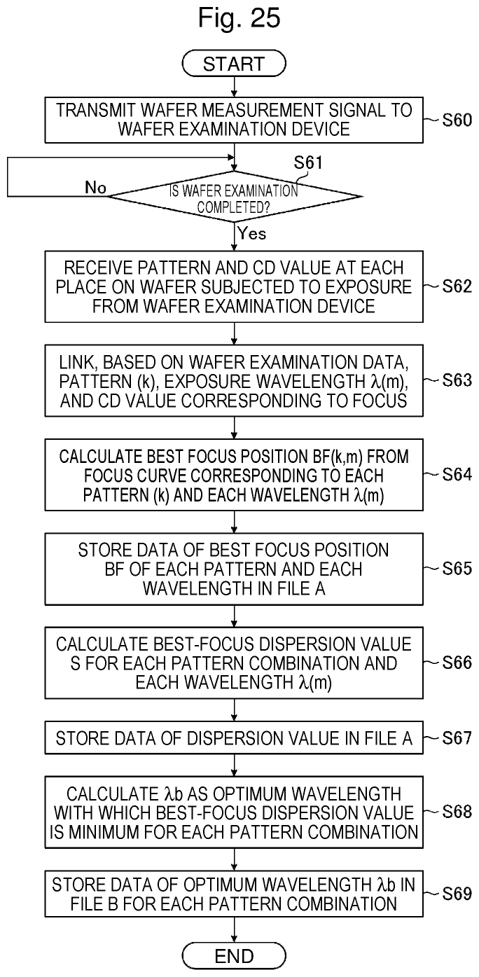

FIG. 25 is a flowchart illustrating exemplary processing at the lithography control unit 110 of Embodiment 3. At step S60, the lithography control unit 110 transmits a measurement signal of the wafer WF to the wafer examination device 310. The wafer examination device 310 performs measurement based on the measurement signal from the lithography control unit 110.

At step S61, the lithography control unit 110 determines whether examination of the wafer WF is completed. For example, when the examination of the wafer WF is completed, the wafer examination device 310 transmits an examination completion signal indicating the examination completion to the lithography control unit 110. The lithography control unit 110 determines whether the examination is completed based on whether the examination completion signal is received.

When the result of the determination at step S61 is “No”, the lithography control unit 110 waits at the current step. When the result of the determination at step S61 is “Yes”, the lithography control unit 110 proceeds to step S62.

At step S62, the lithography control unit 110 receives a pattern and a CD value at each place on the wafer WF subjected to exposure from the wafer examination device 310. Data of the reticle pattern may be stored in advance when it is difficult to acquire information of the pattern from a result of measurement by the wafer examination device 310.

At step S63, the lithography control unit 110 links, based on the wafer examination data, the pattern (k), the wavelength λ(m) of the exposure, and the CD value corresponding to focus.

Then at step S64, the lithography control unit 110 calculates the best focus position BF(k,m) from the focus curve corresponding to each pattern (k) and each wavelength λ(m).

Then at step S65, the lithography control unit 110 stores data of the best focus position BF of each pattern and each wavelength in the file A.

Then at step S66, the lithography control unit 110 calculates the best-focus dispersion value S for each combination of patterns and the wavelength λ(m). Then at step S67, the lithography control unit 110 stores data of the dispersion value S obtained through the calculation in the file A.

Then at step S68, the lithography control unit 110 calculates λb as an optimum wavelength with which the best-focus dispersion value S is minimum for each combination of patterns. Then at step S69, the lithography control unit 110 stores data of the optimum wavelength λb in the file B for each combination of patterns.

After step S69, the lithography control unit 110 ends the flowchart in FIG. 25.

5.3 Effect

With the lithography system 103 according to Embodiment 3, the focus difference between reticle patterns due to the mask three-dimensional effect can be corrected based on a result of actual exposure of the wafer WF. Accordingly, the focus difference between mask patterns due to the mask three-dimensional effect can be corrected by adjusting the wavelength of a pulse laser beam for a pattern combination in accordance with the locations of the reticle patterns during scanning exposure.

Moreover, according to Embodiment 3, data of the files A and B can be constantly updated based on a result of actual exposure, and thus exposure can be performed at a wavelength optimum for an exposure process at the time. Accordingly, the CDU of a resist pattern improves.

5.4 Other

In Embodiment 3, initial data of the files A and B may be produced by performing test exposure first. Procedures of producing data of the files A and B through execution of the test exposure are, for example, as follows.

[Procedure a] At each scanning of the wafer WF, the target wavelength λt of the laser apparatus 12 and the focus position of the exposure apparatus 14 are changed and exposure is performed.

[Procedure b] First (initial) files A and B may be produced based on an examination result of the wafer WF exposed through the procedure a and the wavelength and focus position of the exposure at the time.

### 6. Dispersion of Best Focus Positions of Patterns

Dispersion of the best focus positions of patterns included in a combination of multiple kinds of patterns is not limited to the arithmetic mean square of deviation but the dispersion value may be calculated with weights in accordance with the patterns. For example, when the square sum of deviation is calculated, the dispersion value may be calculated with multiplication by weights reflecting importance based on the kinds of circuits. Alternatively, weighting may be performed in accordance with the area ratio of each pattern, and the dispersion value may be calculated with a larger weight on a pattern that occupies a larger area. Alternatively, the dispersion value may be calculated with a larger weight on a pattern (for example, a gate circuit part) that provides important influence for circuit operation.

Standard deviation is defined as the positive square root of dispersion, and thus minimization of dispersion implies minimization of standard deviation. It is not essential difference whether dispersion or standard deviation is used as a numerical value for evaluating the degree of dispersion of data, and it is clear that evaluation of dispersion in the present specification may be replaced with evaluation of standard deviation.

### 7. Exemplary Excimer Laser Apparatus that Uses Solid-State Laser Device as Oscillator

7.1 Configuration

The laser apparatus 12 of the configuration exemplarily described with reference to FIG. 8 includes a line narrowed gas laser apparatus as the oscillator 22, but the configuration of a laser apparatus is not limited to the example in FIG. 8.

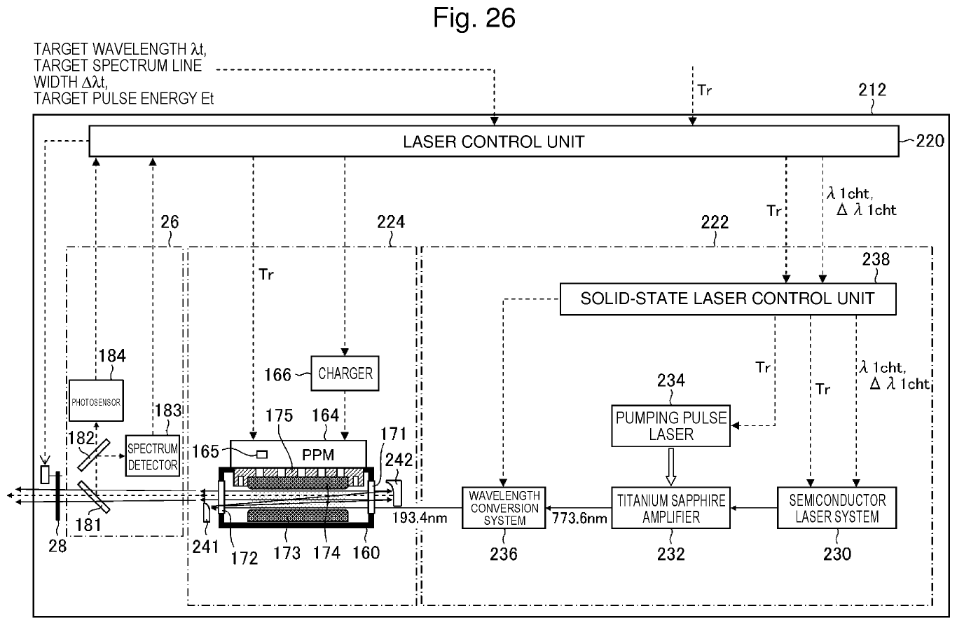

A laser apparatus 212 illustrated in FIG. 26 may be used in place of the laser apparatus 12 illustrated in FIG. 8. In the configuration illustrated in FIG. 26, an element common or similar to that in FIG. 8 is denoted by the same reference sign, and thus description will be omitted.

The laser apparatus 212 illustrated in FIG. 26 is an excimer laser apparatus that uses a solid-state laser device as an oscillator, and includes a solid-state laser system 222, an excimer amplifier 224, and a laser control unit 220.

The solid-state laser system 222 includes a semiconductor laser system 230, a titanium sapphire amplifier 232, a pumping pulse laser 234, a wavelength conversion system 236, and a solid-state laser control unit 238.

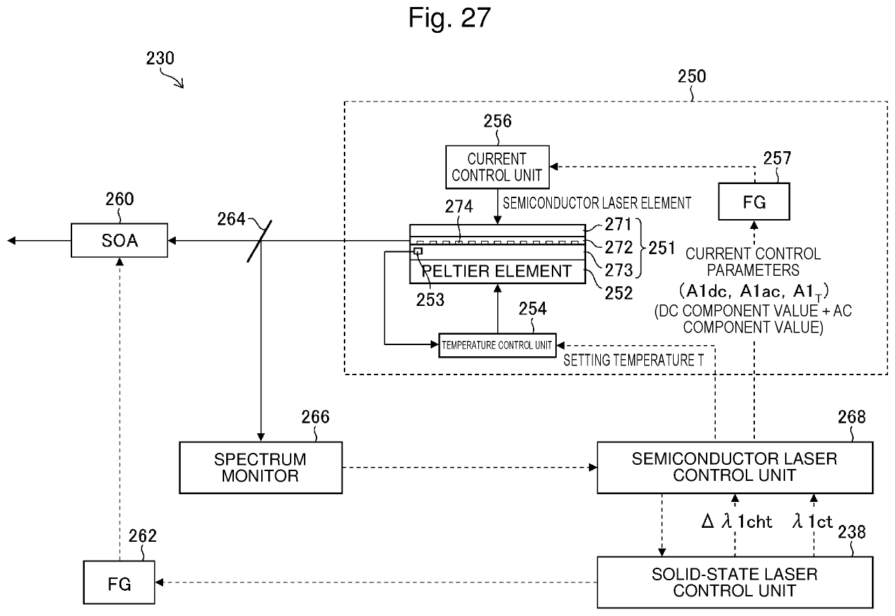

The semiconductor laser system 230 includes a distributed-feedback (DFB) semiconductor laser configured to emit a CW laser beam having a wavelength of 773.6 nm approximately and a semiconductor optical amplifier (SOA) configured to generate pulses of the CW laser beam. An exemplary configuration of the semiconductor laser system 230 will be described later with reference to FIG. 27.

The titanium sapphire amplifier 232 includes titanium sapphire crystal. The titanium sapphire crystal is disposed on the optical path of a pulse laser beam subjected to pulse amplification at the SOA of the semiconductor laser system 230. The pumping pulse laser 234 may be a laser apparatus configured to emit second-order harmonic light of a YLF laser. Yttrium lithium fluoride (YLF) is solid-state laser crystal expressed by the chemical formula LiYF₄.

The wavelength conversion system 236 includes a plurality of non-linear optical crystals, performs wavelength conversion of an incident pulse laser beam, and emits a fourth-order harmonic pulse laser beam. The wavelength conversion system 236 includes, for example, LBO crystal and KBBF crystal. The LBO crystal is non-linear optical crystal expressed by the chemical formula LiB₃O₅. The KBBF crystal is non-linear optical crystal expressed by the chemical formula KBe₂BO₃F₂. Each crystal is disposed on a non-illustrated rotation stage so that the incident angle on the crystal can be changed.

The solid-state laser control unit 238 controls the semiconductor laser system 230, the pumping pulse laser 234, and the wavelength conversion system 236 in accordance with a command from the laser control unit 220.

The excimer amplifier 224 includes the chamber 160, the PPM 164, the charger 166, a convex mirror 241, and a concave mirror 242. The chamber 160 includes the windows 171 and 172, the pair of electrodes 173 and 174, and the electrically insulating member 175. ArF laser gas is introduced into the chamber 160. The PPM 164 includes the switch 165 and the charging capacitor.

The excimer amplifier 224 has a configuration in which seed light having a wavelength of 193.4 nm is amplified by passing through a discharge space between the pair of electrodes 173 and 174 three times. The seed light having a wavelength of 193.4 nm is a pulse laser beam emitted from the solid-state laser system 222.

The convex mirror 241 and the concave mirror 242 are disposed outside the chamber 160 so that the pulse laser beam emitted from the solid-state laser system 222 is expanded by passing three times.

The seed light having a wavelength of 193.4 nm approximately and having entered the excimer amplifier 224 passes through a discharge space between a pair of discharge electrodes 412 and 413 three times by being reflected at the convex mirror 241 and the concave mirror 242. Accordingly, the beam of the seed light is enlarged and amplified.

7.2 Operation

When having received the target wavelength λt, the target spectrum line width Δλt, and the target pulse energy Et from the exposure control unit 40, the laser control unit 220 calculates, from table data, an approximate expression, or the like, a target wavelength λ1ct and a target spectrum line width Δλ1cht of a pulse laser beam from the semiconductor laser system 230 with which the target values are achieved.

The laser control unit 220 transmits the target wavelength λ1ct and the target spectrum line width Δλ1cht to the solid-state laser control unit 238 and sets charging voltage to the charger 166 such that a pulse laser beam emitted from the excimer amplifier 224 has the target pulse energy Et.

The solid-state laser control unit 238 controls the semiconductor laser system 230 such that the wavelength and spectrum line width of a pulse laser beam emitted from the semiconductor laser system 230 become closer to the target wavelength λ1ct and the target spectrum line width Δλ1cht. The scheme of the control performed by the solid-state laser control unit 238 will be described later with reference to FIGS. 27 to 30.

In addition, the solid-state laser control unit 238 controls two non-illustrated rotation stages to achieve such an incident angle that wavelength conversion efficiency of the LBO crystal and the KBBF crystal of the wavelength conversion system 236 is maximum.

When the light emission trigger signal Tr is transmitted from the exposure control unit 40 to the laser control unit 220, a trigger signal is input to the semiconductor laser system 230, the pumping pulse laser 234, and the switch 165 of the PPM 164 of the excimer amplifier 224 in synchronization with the light emission trigger signal Tr. As a result, pulse current is input to the SOA of the semiconductor laser system 230, and a pulse-amplified pulse laser beam is emitted from the SOA.

The pulse laser beam is emitted from the semiconductor laser system 230 and further pulse-amplified at the titanium sapphire amplifier 232. The pulse laser beam then enters the wavelength conversion system 236. As a result, the pulse laser beam of the target wavelength λt is emitted from the wavelength conversion system 236.

When having received the light emission trigger signal Tr from the exposure control unit 40, the laser control unit 220 transmits a trigger signal to each of a SOA 260 of the semiconductor laser system 230 to be described later, the switch 165 of the PPM 164, and the pumping pulse laser 234 such that discharge occurs when a pulse laser beam emitted from the solid-state laser system 222 enters the discharge space of the chamber 160 of the excimer amplifier 224.

As a result, the pulse laser beam emitted from the solid-state laser system 222 is amplified at the excimer amplifier 224 through three-time passing. The pulse laser beam amplified by the excimer amplifier 224 is sampled by the beam splitter 181 of the monitor module 26, the pulse energy E is measured by using the photosensor 184, and the wavelength λ and the spectrum line width Δλ are measured by using the spectrum detector 183.

The laser control unit 220 may correct and control the charging voltage of the charger 166 and the wavelength λ1ct and the spectrum line width Δλ1cht of the pulse laser beam emitted from the semiconductor laser system 230 based on the pulse energy E, the wavelength λ, and the spectrum line width Δλ measured by using the monitor module 26 such that the difference between the pulse energy E and the target pulse energy Et, the difference between the wavelength λ and the target wavelength λt, and the difference between the spectrum line width Δλ and the target spectrum line width Δλt each become closer to zero.

7.3 Description of Semiconductor Laser System

7.3.1 Configuration

FIG. 27 illustrates an exemplary configuration of the semiconductor laser system 230. The semiconductor laser system 230 includes a distributed-feedback semiconductor laser 250 of a single longitudinal mode, a semiconductor optical amplifier (SOA) 260, a function generator (FG) 262, a beam splitter 264, a spectrum monitor 266, and a semiconductor laser control unit 268. The distributed-feedback semiconductor laser is referred to as a “DFB laser”.

The DFB laser 250 emits a continuous wave (CW) laser beam having a wavelength of 773.6 nm approximately. The DFB laser 250 can change its oscillation wavelength by current control and/or temperature control.

The DFB laser 250 includes a semiconductor laser element 251, a Peltier element 252, a temperature sensor 253, a temperature control unit 254, a current control unit 256, and a function generator 257. The semiconductor laser element 251 includes a first clad layer 271, an active layer 272, and a second clad layer 273 and includes a grating 274 at the boundary between the active layer 272 and the second clad layer 273.

7.3.2 Operation

The DFB laser 250 has an oscillation central wavelength that can be changed by changing a setting temperature T and/or a current value A of the semiconductor laser element 251.

When a spectrum line width is controlled by chirping the oscillation wavelength of the DFB laser 250 at high speed, the control of the spectrum line width can be performed by changing the current value A of current flowing through the semiconductor laser element 251 at high speed.

Specifically, a central wavelength λ1chc and a spectrum line width Δλ1ch of the pulse laser beam emitted from the semiconductor laser system 230 can be controlled at high speed by transmitting values of parameters of a DC component value A1dc, a variation width A1ac of an AC component, and a period A1_{T} of the AC component as current control parameters from the semiconductor laser control unit 268 to the function generator 257.

The spectrum monitor 266 may measure wavelength by using, for example, a spectrometer or a heterodyne interferometer.

The function generator 257 outputs, to the current control unit 256, an electric signal having a waveform in accordance with a current control parameter designated by the semiconductor laser control unit 268. The current control unit 256 performs current control such that current in accordance with the electric signal from the function generator 257 flows through the semiconductor laser element 251. Note that the function generator 257 may be provided outside the DFB laser 250. For example, the function generator 257 may be included in the semiconductor laser control unit 268.

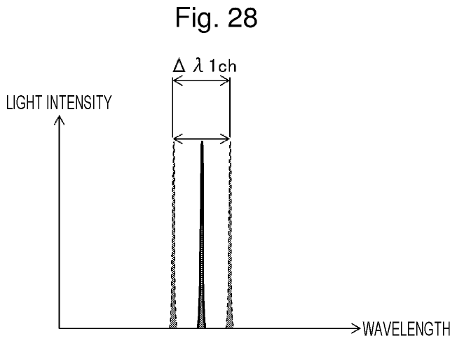

FIG. 28 is a conceptual diagram of a spectrum line width achieved by chirping. The spectrum line width Δλ1ch is measured as the difference from a maximum wavelength and a minimum wavelength generated by chirping.

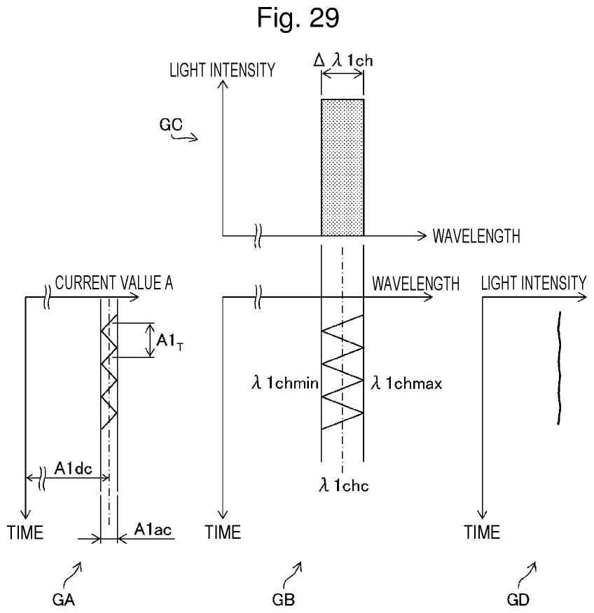

FIG. 29 is a schematic diagram illustrating the relation among current flowing through the semiconductor laser, wavelength change by chirping, a spectrum waveform, and light intensity. A graph GA displayed at a lower-left part of FIG. 29 is a graph illustrating change of the current value A of current flowing through the semiconductor laser element 251. A graph GB displayed at a lower-central part of FIG. 29 is a graph illustrating chirping caused by the current of the graph GA. A graph GC displayed at an upper part of FIG. 29 is a schematic diagram of a spectrum waveform obtained by the chirping of the graph GB. A graph GD displayed at a lower-right part of FIG. 29 is a graph illustrating change of the light intensity of a laser beam emitted from the semiconductor laser system 230 due to the current of the graph GA.

Current control parameters of the semiconductor laser system 230 include the following values as illustrated in the graph GA.

A1dc: DC component value of current flowing through the semiconductor laser element

A1ac: variation width of the AC component of current flowing through the semiconductor laser element (the difference between a maximal value and a minimal value of the current)

A1_{T}: period of the AC component of current flowing through the semiconductor laser element

In the example illustrated in FIG. 29, triangular wave is illustrated as an exemplary AC component of a current control parameter, and variation of light intensity of the CW laser beam emitted from the DFB laser 250 due to variation of triangular-wave current is small.

The relation between a time width D_{TW} of an amplification pulse of the SOA 260 and the period A1_{T} of the AC component preferably satisfies Expression (1) below.

D_{TW}=n·A1_{T} (1)

where n is an integer equal to or larger than one.

When the relation of Expression (1) is satisfied, change of the spectrum waveform of an amplified pulse laser beam can be suppressed irrespective of the timing of pulse amplification at the SOA 260.

Even when Expression (1) is not satisfied, a pulse width range at the SOA 260 is, for example, 10 ns to 50 ns. The period A1_{T} of the AC component of current flowing through the semiconductor laser element 251 is sufficient shorter than the pulse width of the SOA 260 (the time width D_{TW} of an amplification pulse). For example, the period A1_{T} is preferably 1/1000 to 1/10 of the pulse width of the SOA 260. More preferably, the period A1_{T} may be 1/1000 to 1/100 of the pulse width.

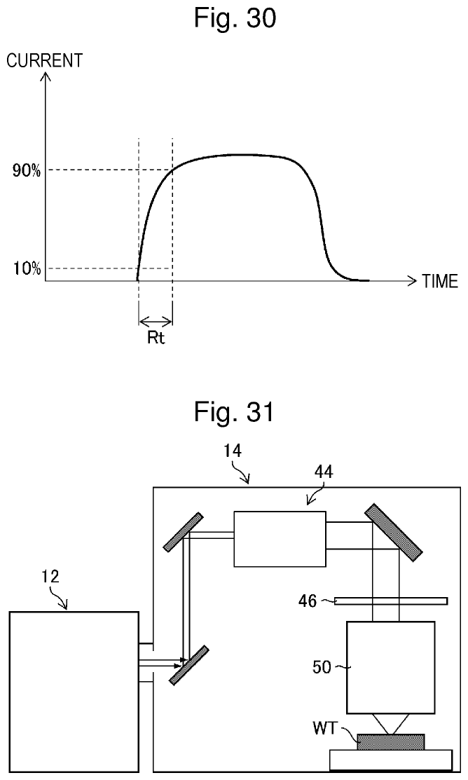

The SOA 260 preferably has a rising time that is, for example, equal to or smaller than 2 ns, more preferably equal to or smaller than 1 ns. The rising time is a time Rt required when the amplitude of the waveform of pulse current increases from 10% to 90% of a maximum amplitude as illustrated in FIG. 30.

7.3.3 Other

In the example illustrated in FIG. 29, triangular wave is illustrated as an exemplary waveform of the AC component of current, but the present invention is not limited to this example and the waveform may be any waveform that changes in a constant period, for example. Examples of the waveform of the AC component other than triangular wave include sine wave and square wave. Various target spectrum waveforms can be generated by controlling the waveform of the AC component.

7.4 Effect

The laser apparatus 212, which uses the solid-state laser system 222 as an oscillator, has the following advantages over a case in which an excimer laser is used as an oscillator.

[1] The solid-state laser system 222 can control the wavelength λ and the spectrum line width Δλ at high speed and high accuracy by controlling the current value A of the DFB laser 250. Specifically, the laser apparatus 212 can control the oscillation wavelength and the spectrum line width Δλ at high speed by controlling the current value A of the DFB laser 250 immediately after receiving data of the target wavelength λt and the target spectrum line width Δλt. Thus, the wavelength λ and the spectrum line width Δλ of a pulse laser beam emitted from the laser apparatus 212 can be changed and controlled at high speed and high accuracy for each pulse.

[2] Moreover, spectrum waveforms of various functions, which are different from a normal spectrum waveform can be generated through chirping by controlling the current value A of the DFB laser 250.

[3] Thus, a laser apparatus that includes an oscillator using a solid-state laser system 222 including a DFB laser 250 and includes an excimer amplifier 224 is preferable for controlling the wavelength or spectrum line width obtained from a spectrum waveform of the moving integrated value of a spectrum waveform as a laser control parameter.

7.5 Other

An embodiment of a solid-state laser device is not limited to the example illustrated in FIGS. 26 to 30 and may be, for example, a solid-state laser system including a DFB laser having a wavelength of 1547.2 nm approximately and a SOA, and a wavelength conversion system may be a laser apparatus configured to emit eighth-order harmonic light of 193.4 nm. Another solid-state laser device may be a system including a CW oscillation DFB laser and a SOA and configured to pulse-amplify wavelength by controlling the current value of current flowing through the DFB laser and causing pulse current to flow through the SOA.

In the example illustrated in FIG. 26, a multi-pass amplifier is illustrated as an exemplary excimer amplifier, but the present invention is not limited to this embodiment, and the excimer amplifier may be, for example, an amplifier including an optical resonator such as a Fabry-Perot resonator or a ring resonator.

### 8. Hardware Configurations of Various Control Units

A control device that functions as the laser control unit 20, the exposure control unit 40, the lithography control unit 110, the solid-state laser control unit 238, the semiconductor laser control unit 268, and any other control unit can be achieved by hardware and software combination of one or a plurality of computers. The software is synonymous with a program. The computers conceptually include a programmable controller. Each computer may include a central processing unit (CPU) and a storage device such as a memory. The CPU is an example of a processor.

A storage device is a non-transitory computer-readable medium as a tangible entity and includes, for example, a memory that is a main storage device and a storage that is an auxiliary storage device. The computer-readable medium may be, for example, a semiconductor memory, a hard disk drive (HDD) device, a solid-state drive (SSD) device, or a combination of a plurality of these devices. A program executed by a processor is stored in the computer-readable medium.

Some or all of processing functions of the control device may be implemented by using an integrated circuit such as a field programmable gate array (FPGA) or an application specific integrated circuit (ASIC).

Functions of a plurality of control devices can be implemented by a single control device. Moreover, in the present disclosure, the control device may be connected with each other through a communication network such as a local area network or the Internet. In a distributed computing environment, a program unit may be stored in local and remote memory storage devices.

### 9. Electronic Device Manufacturing Method

FIG. 31 schematically illustrates an exemplary configuration of the exposure apparatus 14. The exposure apparatus 14 includes the illumination optical system 44 and the projection optical system 50. The illumination optical system 44 illuminates, with a laser beam incident from the laser apparatus 12, the reticle pattern of the reticle 46 disposed on the non-illustrated reticle stage 48. The laser beam having transmitted through the reticle 46 is subjected to reduced projection through the projection optical system 50 and imaged on a non-illustrated workpiece disposed on a workpiece table WT. The workpiece may be a photosensitive substrate such as a semiconductor wafer to which resist is applied. The workpiece table WT may be the wafer stage 54.

The exposure apparatus 14 translates the reticle stage 48 and the workpiece table WT in synchronization so that the workpiece is exposed to the laser beam on which the reticle pattern is reflected. A semiconductor device can be manufactured through a plurality of processes after the reticle pattern is transferred onto the semiconductor wafer through the exposure process as described above. The semiconductor device is an example of an “electronic device” in the present disclosure.

The laser apparatus 12 in FIG. 31 may be, for example, the laser apparatus 212 including the solid-state laser system 222, which is described with reference to FIG. 26.

### 10. Other

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. An exposure system that performs scanning exposure of a semiconductor substrate by irradiating a reticle with a pulse laser beam, the exposure system comprising:
a laser apparatus configured to emit the pulse laser beam;
an illumination optical system through which the pulse laser beam is guided to the reticle;
a reticle stage configured to move the reticle; and
a processor configured to control emission of the pulse laser beam from the laser apparatus and movement of the reticle by the reticle stage,
the reticle including a region in which multiple kinds of patterns are arranged in a mixed manner in a scanning width direction orthogonal to a scanning direction of the scanning exposure,
the processor being configured to instruct the laser apparatus about a target wavelength of the pulse laser beam such that the laser apparatus emits the pulse laser beam of a wavelength with which dispersion of best focus positions corresponding to respective patterns of the multiple kinds of patterns is minimum.

2. The exposure system according to claim 1, wherein the processor is configured to
calculate the best focus positions of the respective patterns of the multiple kinds of patterns with different wavelengths of the pulse laser beam, and
calculate the wavelength with which the dispersion of the best focus positions of the respective patterns of the multiple kinds of patterns is minimum for each combination of the multiple kinds of patterns.

3. The exposure system according to claim 1, wherein each of the best focus positions corresponding to the respective patterns of the multiple kinds of patterns is a position of best focus at which a critical dimension of each of the multiple kinds of patterns has an extreme value on a focus curve representing a relation between the critical dimension and focus.

4. The exposure system according to claim 1, wherein the processor is configured to calculate the best focus positions corresponding to the respective patterns of the multiple kinds of patterns by executing a lithography simulation program including an electromagnetic field analysis function.

5. The exposure system according to claim 1, further comprising a projection optical system through which an image of the reticle is projected onto the semiconductor substrate, wherein the processor is configured to
calculate the best focus positions corresponding to the respective patterns of the multiple kinds of patterns by using a plurality of pieces of data including a parameter of the illumination optical system, a parameter of the projection optical system, a parameter of a resist applied on the semiconductor substrate, a reticle pattern of the reticle, and a control parameter of the pulse laser beam,
calculate, for each combination of the multiple kinds of patterns, dispersion of the best focus positions corresponding to the respective patterns of the multiple kinds of patterns included in the combination, and
calculate the wavelength of the pulse laser beam with which the dispersion is minimum.

6. The exposure system according to claim 5, wherein the processor is configured to
calculate the best focus positions corresponding to the respective patterns of the multiple kinds of patterns with different wavelengths as the control parameter of the pulse laser beam,
calculate, for each combination of the multiple kinds of patterns, dispersion of the best focus positions corresponding to the respective patterns of the multiple kinds of patterns included in the combination, and
store the best focus positions corresponding to the respective patterns of the multiple kinds of patterns and the dispersion of the best focus positions corresponding to the combination in a first file in association with the wavelength, the best focus positions being obtained through the calculation.

7. The exposure system according to claim 6, wherein the processor is configured to
calculate the wavelength of the pulse laser beam with which the dispersion is minimum for each combination of the multiple kinds of patterns based on data of the first file, and
associate and store the combination of the multiple kinds of patterns and the wavelength of the pulse laser beam with which the dispersion is minimum in a second file.

8. The exposure system according to claim 1, wherein the processor is configured to calculate the best focus positions corresponding to the respective patterns of the multiple kinds of patterns by performing electromagnetic field analysis by using information including a geometric dimension and a physical property value of a material of each of the multiple kinds of patterns, the geometric dimension defining a three-dimensional structure of a reticle pattern.

9. The exposure system according to claim 1, further comprising a server configured to manage a parameter used for the scanning exposure, wherein the server is configured to
calculate the best focus positions corresponding to the respective patterns of the multiple kinds of patterns with different wavelengths of the pulse laser beam, and
calculate the wavelength with which the dispersion of the best focus positions corresponding to the respective patterns of the multiple kinds of patterns is minimum for each combination of the multiple kinds of patterns.

10. The exposure system according to claim 1, wherein the processor is configured to
use a second file including data in which each combination of the multiple kinds of patterns is associated with the wavelength of the pulse laser beam with which the dispersion of the best focus positions corresponding to the respective patterns of the multiple kinds of patterns is minimum, and
calculate a target wavelength of the pulse laser beam in the region including the multiple kinds of patterns for each pulse.

11. The exposure system according to claim 1, wherein the processor is configured to control the laser apparatus based on a wavelength of a moving integration spectrum of the pulse laser beam with which a scanning field of the semiconductor substrate is exposed.

12. The exposure system according to claim 1, wherein, when a Y axial direction is defined to be the scanning direction of the scanning exposure and a By width is defined to be a Y axial direction beam width of a scanning beam of the pulse laser beam with which the reticle is scanned toward a positive side in the Y axial direction, the processor is configured to
calculate, based on information of a reticle pattern of the reticle, expanded regions in which respective regions of the patterns are expanded by shifting boundaries of the multiple kinds of patterns on a negative side in the Y axial direction toward the negative side in the Y axial direction by a distance corresponding to the By width, and
calculate, for each pulse, the target wavelength of the pulse laser beam with which a scanning field is exposed based on a second file including data in which each combination of the multiple kinds of patterns is associated with the wavelength of the pulse laser beam with which the dispersion of the best focus positions corresponding to the respective patterns of the multiple kinds of patterns is minimum, the combination of the multiple kinds of patterns in the scanning field, and locations of the respective expanded regions of the patterns.

13. The exposure system according to claim 1, further comprising an examination device configured to measure a critical dimension of an exposure-completed semiconductor substrate on which the scanning exposure is performed, wherein the processor is configured to calculate, based on a result of measurement using the examination device and information of a reticle pattern of the reticle, the wavelength of the pulse laser beam with which the dispersion of the best focus positions corresponding to the respective patterns of the multiple kinds of patterns is minimum.

14. The exposure system according to claim 13, wherein the processor is configured to
associate a pattern formed on the exposure-completed semiconductor substrate by exposure, a wavelength of the pulse laser beam with which the exposure is performed, and the best focus position, with a value of a critical dimension corresponding to the pattern, the wavelength, and the best focus position,
calculate, for each of the multiple kinds of patterns and each wavelength, the best focus position at which a critical dimension has an extreme value on a focus curve representing a relation between the critical dimension and focus,
store data of the best focus position corresponding to the pattern and the wavelength in a first file,
calculate a dispersion value of the best focus position for each combination of the multiple kinds of patterns and each wavelength,
store data of the dispersion value of the best focus position calculated for the combination of patterns in the first file,
calculate the wavelength of the pulse laser beam with which the dispersion value is minimum for the combination of patterns based on the data of the first file, and
associate and store the combination of patterns and the wavelength of the pulse laser beam with which the dispersion value is minimum in a second file.

15. The exposure system according to claim 1, wherein
the laser apparatus is an excimer laser apparatus including
an oscillator, and
an amplifier configured to amplify a pulse laser beam emitted from the oscillator, and
the oscillator includes a line narrowing module.

16. The exposure system according to claim 1, wherein
the laser apparatus is an excimer laser apparatus including
an oscillator, and
an amplifier configured to amplify a pulse laser beam emitted from the oscillator, and
the oscillator is a solid-state laser system using a distributed-feedback semiconductor laser.

17. A method of producing a laser control parameter, the method being executed by a processor,
the laser control parameter including a wavelength of a pulse laser beam with which a reticle is irradiated,
the method comprising:
calculating, by the processor, best focus positions corresponding to respective patterns of multiple kinds of patterns included in the reticle;
calculating, by the processor, for each combination of the multiple kinds of patterns, a wavelength of the pulse laser beam with which dispersion of the best focus positions corresponding to the respective patterns of the multiple kinds of patterns included in the combination is minimum; and
associating and storing, by the processor, the combination of the multiple kinds of patterns and the wavelength of the pulse laser beam with which the dispersion is minimum in a file.

18. The method of producing the laser control parameter according to claim 17, further comprising:
calculating, by the processor, the best focus positions corresponding to the respective patterns of the multiple kinds of patterns by using a plurality of pieces of data including
a parameter of an illumination optical system through which the pulse laser beam is guided to the reticle,
a parameter of a projection optical system through which an image of the reticle is projected onto a semiconductor substrate,
a parameter of a resist applied on the semiconductor substrate,
a reticle pattern of the reticle,
a geometric dimension that defines a three-dimensional structure of the reticle pattern,
a physical property value of a material of each of the multiple kinds of patterns, and
a control parameter of the pulse laser beam; and
performing, by the processor, the calculation of the best focus positions corresponding to the respective patterns of the multiple kinds of patterns a plurality of times with different values of the wavelength of the pulse laser beam to calculate the wavelength of the pulse laser beam with which the dispersion of the best focus positions corresponding to the respective patterns of the multiple kinds of patterns is minimum.

19. The method of producing the laser control parameter according to claim 17, further comprising receiving, by the processor, a measurement result obtained by using an examination device configured to measure a critical dimension of an exposure-completed semiconductor substrate on which scanning exposure is performed by irradiating the reticle with the pulse laser beam, wherein
the processor calculates the best focus positions corresponding to the respective patterns of the multiple kinds of patterns based on the measurement result and information of a reticle pattern of the reticle, and
the processor calculates the wavelength of the pulse laser beam with which the dispersion of the best focus positions corresponding to the respective patterns of the multiple kinds of patterns is minimum based on a plurality of the measurement results obtained by performing the scanning exposure a plurality of times with different values of the wavelength of the pulse laser beam.

20. An electronic device manufacturing method comprising performing scanning exposure of a photosensitive substrate by irradiating a reticle with a pulse laser beam by using an exposure system to manufacture an electronic device,
the exposure system including
a laser apparatus configured to emit the pulse laser beam,
the reticle,
an illumination optical system through which the pulse laser beam is guided to the reticle,
a reticle stage configured to move the reticle, and
a processor configured to control emission of the pulse laser beam from the laser apparatus and movement of the reticle by the reticle stage,
the reticle including a region in which multiple kinds of patterns are arranged in a mixed manner in a scanning width direction orthogonal to a scanning direction of the scanning exposure,
the processor being configured to instruct the laser apparatus about a target wavelength of the pulse laser beam such that the laser apparatus emits the pulse laser beam of a wavelength with which dispersion of best focus positions corresponding to respective patterns of the multiple kinds of patterns is minimum.
